(19) United States
(12) Patent Application Publication
(10) Pub. No.: US 2025/0244669 A1
(43) Pub. Date: Jul. 31, 2025

(54) COMPOSITIONS AND METHODS OF IMPROVING METAL STRUCTURE FABRICATION BY WET CHEMICAL ETCH

(71) Applicant: Merck Patent GmbH, Darmstadt (DE)

(72) Inventors: Zhong LI, Bridgewater, NJ (US); Hengpeng WU, Hillsborough (NJ); Chunwei CHEN, Whitehouse Station, NJ (US); Weihong LIU, Branchburg, NJ (US)

(21) Appl. No.: 18/704,185

(22) PCT Filed: Nov. 15, 2022
(86) PCT No.: PCT/EP2022/081910

§ 371 Date: Apr. 24, 2024

Related U.S. Application Data
(60) Provisional application No. 63/280,302, filed on Nov. 17, 2021.

(51) Int. Cl. G03F 7/032; G03F 7/039; G03F 7/16

(52) U.S. Cl. CPC G03F 7/032; G03F 7/039; G03F 7/16

(57) ABSTRACT

One aspect of this invention is a photoresist composition comprising a thiol derivatives where the thiol moiety is attached to an SP2 carbon which is part of ring which has structures (H1), (H2) (H3), or (H4), and where this thiol additive is present in a range of about 0.5 wt. % to about 3 wt. % of total solids. Another aspect of this invention is to use this photoresist composition on a metal substrate a patterned photoresist which is use as a etch mask in anisotropic wet chemical etching of the metal substate to produce a patterned metallic substrate. Yet Another aspect of this invention is a composition which comprises the above-described thiol derivatives in a spin casting solution and the process of treating a metal substrate which allows overlaid patterned photo resist to be used as an etch mask for wet chemical etching to affect anisotropic etching of the metal substate to also generate patterned metallic substate.

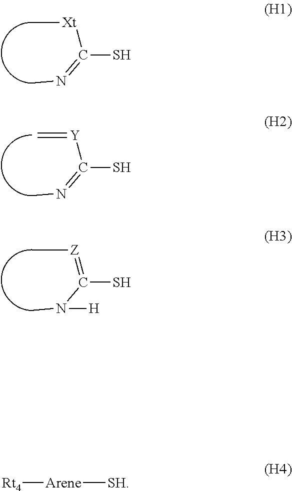

### FIELD

The disclosed subject matter pertains to photoresist composition, and spin casting solvent composition comprising thiol derivatives and the process of using these to improved metal structure fabrication by wet chemical etch.

### BACKGROUND

Photoresist compositions are used in microlithographic processes for making miniaturized electronic components such as in the fabrication of computer chips, integrated circuits, light emitting diodes (LED) devices and displays. Generally, in these processes, a film of a photoresist composition is first applied to a substrate material, such as silicon wafers used for making integrated circuits. The coated substrate is then baked to evaporate solvent in the photoresist composition and to fix the coating onto the substrate. The baked, coated surface of the substrate is next subjected to an image-wise exposure to imaging radiation.

This radiation exposure causes a chemical transformation in the exposed areas of the coated surface. Visible light, ultraviolet (UV) light, electron beam and X-ray radiant energy are imaging radiation types commonly used today in microlithographic processes. After this image-wise exposure, the coated substrate is treated with a developer solution to dissolve and remove either the radiation-exposed or the unexposed areas of the coated surface of the substrate.

There are two types of photoresist compositions which are developable in aqueous base, negative-working and positive-working. Further, these two types of photoresist compositions may either be chemically amplified photoresists, where the quantum yield of the photochemical event creating different solubility characteristics allowing imaging of these photoresists is amplified by a catalytic chain length, which results in greater sensitivity toward radiation of these chemically amplified photoresists than those that are not chemically amplified, where the photochemical event creating different solubility characteristics allowing imaging of these photoresists is solely predicated by the quantum yield of photosensitive moieties within the photoresist, whose transformation upon irradiation is not amplified by a catalytic event.

When positive-working photoresist compositions are exposed image-wise to radiation, the areas of the resist composition exposed to the radiation become more soluble to a developer solution. In a chemically amplified photoresist of this type, this solubility is achieved by the catalytic release of base solubilizing groups usually by the action of photogenerated acid; this is in contrast to a non-chemically amplified photoresist, where base solubility is usually achieved by the photo-decomposition of dissolution inhibitors such as a DNQ-PAC, where the quantum yield of the photodecomposition of this DNQ-PAC is not amplified by any catalytic event and is therefore not chemically amplified. In both cases the unexposed areas of the photoresist coating remain relatively insoluble to aqueous base. Thus, treatment of an exposed positive-working resist with a developer causes removal of the exposed areas of the photoresist coating and the creation of a positive image in the coating, thereby uncovering a desired portion of the underlying substrate surface on which the photoresist composition was deposited.

When negative-working photoresist compositions are exposed image-wise to radiation, the areas of the resist composition exposed to the radiation become insoluble to a developer solution, while the unexposed areas maintain solubility in aqueous base. In a chemically amplified photoresist of this type this insolubility is achieved by the catalytic release of a reactive moiety such as carbocation which can interact with a crosslinker or the resin itself to render the exposed region insoluble. In contrast in a non-chemically amplified photoresist base insolubility is usually achieved by the photo-generation of a radical which interacts with a crosslinker, usually an acrylate additive to induce crosslinking of the exposed region rendering it insoluble in aqueous base. In both cases the unexposed areas of the photoresist coating remain soluble to such a solution. Thus, treatment of an exposed negative working resist with a developer causes removal of the unexposed areas of the photoresist coating and the creation of a negative image in the coating, thereby uncovering a desired portion of the underlying substrate surface on which the photoresist composition was deposited.

In photoresists used for thick films, the resins are aqueous base soluble resins or their derivatives, usually Novolak resins, (meth)acrylate copolymers with either different methacrylate repeat units or with repeat units derived from hydroxystyrene, or mixtures of these different polymers which contain either carboxylic acid or phenolic base solubilizing groups. For positive chemically amplified photoresists these resins have at least some of these base solubilizing resins in one or more of the polymers with an acid labile group which can be removed by photo-acid generated by a photoacid generator (PAG).

Semiconductor assembly processes have been improved by wafer level packaging (WLP) introduction in high volume manufacturing. Copper (Cu)-Redistribution layer (RDL) miniaturization is one of key processes for small, thin, and light chip manufacturing. Fine pitch redistribution layer (RDL) is the market trend for high density wafer level fan-out (HDWLFO) packaging for semiconductors.

The subtractive way of structuring conductor metals by wet chemical etch was the main technology in the early days of IC (integrated circuit) industry, when Al was the mainstream conductor material. As the miniaturization trend following Moore's Law pushes forward to newer generation CD (critical dimension) nodes, the subtractive way of constructing metal structures, especially by wet chemical etch, could no longer meet the industry requirements. This is mainly because of the isotropic nature of the wet chemical etch that cannot provide high enough fidelity. Alternative subtractive technologies such as plasma dry etch or additive technologies like physical vapor deposition (PVD) or atomic layer deposition (ALD) started dominating the front-end-of-line (FEOL) interconnect fabrications, or additive technologies such as electroplating in the lift-off process (1. NEGATIVE-ACTING CHEMICALLY AMPLIFIED PHOTORESIST COMPOSITION, EP1297386 B1. 2. NEGATIVE RESIST FORMULATION FOR PRODUCING UNDERCUT PATTERN PROFILES, WO 2018/197379 A1) started to be used at the back end of line (BEOL), combining with the conductor material shifting from Al to Cu, as well as to other metals like Co or Rh. But throughput of the additive way of structuring conductor metals is compromised due to either the additional process steps or the inherent slow speed of certain steps like PVD. Also, wet etching of a metal substrate using an overlaid patterned photoresist pattern, is plagued by poor adhesion of the metal to the overlying patterned photoresist which results in an isotropic etching of the underlying metal which causes poor reproducibility and limits the feature size of the resultant patterned metal after wet etching. This is mainly because of the isotropic nature of the wet chemical etch that cannot provide high enough fidelity, although the throughput of the additive way of structuring interconnects is compromised due to either the additional process steps or the inherent slow speed of certain steps like PVD. However, metal wet chemical etch still remains as a favorable technology in a lot of applications such as discrete devices, MEMS (microelectromechanical systems) etc., especially when resolution requirement is more relaxed, and cost benefit is more important. Thus, there is a need for compositions and processes which can improve the wet etching of metal substrates during lithographic processing so that this wet etching is anisotropic and produces an etched metal pattern which has good uniformity and can also resolve smaller etched metal features.

Inherently, wet chemical etch can only be considered for any feature size >3 μm due to its isotropic nature, even though smaller features have been reported by using self-assembly monolayers (SAMs) as ultrathin resist patterned by microcontact printing as opposite to traditional lithography pattering by photoresists. (Microcontact Printing of Alkanethiols on Copper and Its Application in Microfabrication”, Y. Xia et al., Chem. Mater. 1996, 8, 601-603 1). In addition, the typical harsh etch chemistry and lengthy process can lead to undesirable defects ranging from “mouse bites” or notching, photoresist cracking, to extreme cases when photoresist peels off. Poor Resist adhesion at substrates has been generally considered the root cause leading to these defects, which causes poor reproducibility and limits the feature size of the resultant patterned metal after wet etching. However, unlike the well-known adhesion promoting approach using HMDS (hexamethyldisilazane) to prime the substrate surface for Si (Wet etchants penetration through photoresist during wet patterning”, P. Garnier, et al., Solid State Phenomena, 2018, 141-146), there is lack of similar approach and materials for metal substrates (Improved adhesion of novolac and epoxy based resists by cationic organic materials on critical substrates for high volume patterning applications,” A. Voigt, et al., Proc. SPIE 9051, Advances in Patterning Materials and Processes XXXI, 2014, 90511K).

### SUMMARY

Unexpectedly, it has been found that wet etch performance of metal substrates during lithographic patterning and processing of metal substrates could be improved as results of applying a range of thiol derivatives as metal primer to gain improved photoresist adhesion at metal substrates, which solves the typically defect-related issues mentioned above. These thiol derivative metal primers can be either applied as a separate coating as formulation, containing the thiol derivative primer and an organic spin casting solvent, prior to coating the photoresist, or alternatively as an additive in a variety of different type of photoresists including positive and negative photoresists both chemically amplified and non-chemically amplified. Using either approach during conventional wet etch of metal substrates overlaid with imaged photoresist, the improved adhesion of the imaged photoresist pattern over the metal, results in an anisotropically etched metal substrate with fine definition and large side-wall angles avoiding the problem of isotropic etch of the metal caused by poor adhesion of the photoresist to the metal substrate.

One aspect of this invention is a photoresist composition comprising: A thiol derivative where the thiol moiety is attached to an SP2 carbon which is part of a ring which has structures (H1), (H2) (H3), or (H4), and where this thiol derivative is present in a range of about 0.5 wt. % to about 3 wt. % of total solids, wherein in said structure (H1) Xt is selected from the group consisting of N(Rt₃), C(Rt₁)(Rt₂), O, S, Se, and Te; in said structure (H2), Y is selected from the group consisting of C(Rt₃) and N; in said structure (H3), Z is selected from the group consisting of C(Rt₃) and N; and in said structure (H4), where Arene is selected from an unsubstituted phenyl, a substituted phenyl, an unsubstituted polycyclic arene moiety and a substituted polycyclic arene moiety, Rt₁, Rt₂, and Rt₃ are independently selected from the group consisting of H, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms, Rt₄ is independently selected from the group consisting of H, OH, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms.

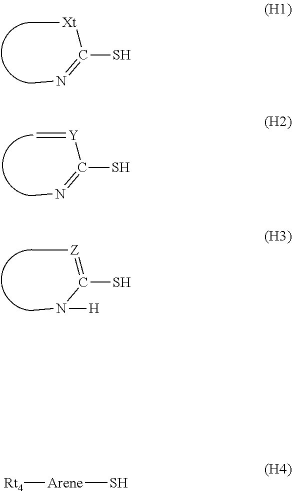

Another aspect of this invention is to use this photoresist composition on a metal substrate for forming a patterned photoresist which is used as a etch mask in anisotropic wet chemical etching of the metal substate to produce a patterned metallic substrate.

Yet Another aspect of this invention is a composition which comprises the above-described thiol derivatives in a spin casting solution and the process of treating a metal substrate with this solution using this substrate for the imaging a photoresist and using the imaged photoresist as a mask against wet chemical etching to affect anisotropic etching of the metal substate to generate a patterned metallic substate.

### BRIEF DESCRIPTION OF THE FIGURES

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter.

FIG. 1 Shows non-limiting examples of DNQ PAC compounds which may be used as a free PAC component and/or be used to form an PAC moiety attached to the polymer component on a phenolic moiety through an acetal comprising linking group.

FIG. 2 Shows non-limiting examples of photoacid generators which generate sulfonic, and other strong acids.

FIG. 3 Shows non-limiting examples of photoacid generators which generate HCl or HBr.

FIG. 4 Shows cross-sectional SEM pictures showing the wet etch performance of copper wafers using the two-step process: Examples 1, 2, where the Cu wafer was primed with PMT, Reference Example which is an untreated Cu wafer and Comparative Example 1 where the wafer was treated with an aliphatic thiol.

FIG. 5 Shows cross-sectional SEM pictures showing the wet etch performance of copper wafers using the two-step process: Examples 3, 4, where the Cu wafer was primed with HPMT and Reference Example which is an untreated Cu wafer.

FIG. 6 Shows cross-sectional SEM pictures comparing the wet etch performance of copper wafers using Examples 5, comparative Example 2, and a reference Cu wafer in which no additive was added to the photoresist

FIG. 7 Shows cross-sectional SEM pictures of Examples 6, 7 and 8, where different levels of PMT was employed as an additive to the photoresist

FIG. 8 Shows cross-sectional SEM pictures of Examples 9 and 10, where different levels of HPMT was employed.

FIG. 9 Shows cross-sectional SEM pictures of Examples 11, 12 and 13, where different levels of HPMT was employed.

FIG. 10 Shows cross-sectional SEM pictures of Examples 14 and 15, which shows a comparison, where photoresists doped with a either PMT or HPMT were used over 4.7 microns Cu layer (top) or a thicker Cu layer of 9 microns (bottom).

### DETAILED DESCRIPTION

It is to be understood that both the foregoing general description and the following detailed description are illustrative and explanatory and are not restrictive of the subject matter as claimed. In this application, the use of the singular includes the plural, the word “a” or “an” means “at least one,” and the use of “or” means “and/or,” unless specifically stated otherwise. Furthermore, the use of the term “including,” as well as other forms such as “includes” and “included,” is not limiting. Also, terms such as “element” or “component” encompass both elements and components comprising one unit and elements or components that comprise more than one unit, unless specifically stated otherwise. As used herein, the conjunction “and” is intended to be inclusive and the conjunction “or” is not intended to be exclusive unless otherwise indicated. For example, the phrase “or, alternatively” is intended to be exclusive. As used herein, the term “and/or” refers to any combination of the foregoing elements including using a single element.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that one or more of the incorporated literature references and similar materials defines a term in a manner that contradicts the definition of that term in this application, this application controls.

Unless otherwise indicated, “alkyl” refers to hydrocarbon groups which can be linear, branched (e.g., methyl, ethyl, propyl, isopropyl, tert-butyl and the like) or cyclic (e.g., cyclohexyl, cyclopropyl, cyclopentyl and the like) multicyclic (e.g., norbornyl, adamantly and the like). These alkyl moieties may be substituted or unsubstituted as described below. The term “alkyl” refers to such moieties with C-1 to C-20 carbons. It is understood that for structural reasons linear alkyls start with C-1, while branched alkyls and cyclic alkyls start with C-3 and multicyclic alkyls start with C-5. Moreover, it is further understood that moieties derived from alkyls described below, such as alkyloxy, have the same carbon number ranges unless otherwise indicated. If the length of the alkyl group is specified as other than described above, the above-described definition of alkyl still stands with respect to it encompassing all types of alkyl moieties as described above and that the structural consideration with regards to minimum number of carbons for a given type of alkyl group still apply.

Alkyloxy (a.k.a. Alkoxy) refers to an alkyl group on which is attached through an oxy (—O—) moiety (e.g., methoxy, ethoxy, propoxy, butoxy, 1,2-isopropoxy, cyclopentyloxy cyclohexyloxy and the like). These alkyloxy moieties may be substituted or unsubstituted as described below.

Halo or halide refers to a halogen, F, Cl, Br or I which is linked by one bond to an organic moiety.

Haloalkyl refers to a linear, cyclic or branched saturated alkyl group such as defined above in which at least one of the hydrogens has been replaced by a halide selected from the group of F, Cl, Br, I or mixture of these if more than one halo moiety is present. Fluoroalkyls are a specific subgroup of these moieties.

Fluoroalkyl refers to a linear, cyclic or branched saturated alkyl group as defined above in which the hydrogens have been replaced by fluorine either partially or fully (e.g., trifluoromethyl, pefluoroethyl, 2,2,2-trifluoroethyl, prefluoroisopropyl, perfluorocyclohexyl and the like). These fluoroalkyl moieties, if not perfluorinated, may be substituted or unsubstituted as described below.

Fluoroalkyloxy refers to a fluoroalkyl group as defined above on which is attached through an oxy (—O—) moiety it may be completed fluorinated (a.k.a. perfluorinated) or alternatively partially fluorinated (e.g., trifluoromethyoxy, perfluoroethyloxy, 2,2,2-trifluoroethoxy, perfluorocyclohexyloxy and the like). These fluoroalkyl moieties, if not pefluorinated may, be substituted or unsubstituted as described below.

Herein when referring to an alkyl, alkyloxy, fluoroalkyl, fluoroalkyloxy moieties with a possible range of carbon atoms which starts with C-1 such as for instance “C-1 to C-20 alkyl,” or “C-1 to C-20 fluoroalkyl,” as non-limiting examples, this range encompasses linear alkyls, alkyloxy, fluoroalkyl and fluoroalkyloxy starting with C-1 but only designated branched alkyls, branched alkyloxy, cycloalkyl, cycloalkyloxy, branched fluoroalkyl, and cyclic fluoroalkyl starting with C-3.

The term “alkylene” refers to hydrocarbon groups which can be linear, branched or cyclic, which have two or more attachment points (e.g., of two attachment points: methylene, ethylene, 1,2-isopropylene, a 1,4-cyclohexylene and the like; of three attachment points 1,1,1-subsituted methane, 1,1,2-subsituted ethane, 1,2,4-subsituted cyclohexane and the like). Here again, when designating a possible range of carbons, such as C-1 to C-20, as a non-limiting example, this range encompasses linear alkylenes starting with C-1 but only designates branched alkylenes, or cycloalkylene starting with C-3. These alkylene moieties may be substituted or unsubstituted as described below.

The term solid component as used herein refers to components which are not the organic spin casting solvent component. Thus the wt. % of total solids refers to the wt. % of an individual solid component versus the sum of all solid components.

The terms “mono and “oligomeric” alkyleneoxyalkylene” encompasses both simple alkyleneoxyalkylene moiety such as ethyleneoxyethylene (—CH₂—CH₂—O—CH₂—CH₂—), propyleneoxypropylene (—CH₂—CH₂—CH₂—O—CH₂—CH₂—CH₂—), and the like, and also oligomeric materials such as di(ethyleneoxy)ethylene (—CH₂—CH₂—O—CH₂—CH₂—O—CH₂—CH₂—), di(propyleneoxy)propylene, (—CH₂—CH₂—CH₂—O—CH₂—CH₂—CH₂—O—CH₂—CH₂—CH₂—), and the like.

The term “aryl” or “aromatic groups” refers to such groups which contain 6 to 24 carbon atoms including phenyl, tolyl, xylyl, naphthyl, anthracyl, biphenyls, bis-phenyls, tris-phenyls and the like. These aryl groups may further be substituted with any of the appropriate substituents, e.g., alkyl, alkoxy, acyl or aryl groups mentioned hereinabove.

The term “Novolak” (a.k.a. Novolac) if used herein without any other modifier of structure, refers to Novolak resins which are soluble in aqueous bases such as tetramethylammonium hydroxide (TMAH) and the like.

The term “PAG,” unless otherwise described, refers to a photoacid generator that can generate acid (a.k.a. photoacid) under deep UV or UV irradiation such as 200-300 nm, i-line, h-line, g-line and/or broadband irradiation. The acid may be a sulfonic acid, HCl, HBr, HAsF₆, and the like. It includes as non-limiting examples onium salts and other photosensitive compounds as known in the art that can photochemically generate strong acids such as alkylsulfonic acid, arylsulfonic acid, HAsF₆, HSbF₆, HBF₄, HPF₆, CF₃SO₃H, HC(SO₂CF3)₂, HC(SO₂CF₃)₃, HN(SO₂CF₃)₂, HB(C₆H₅)₄, HB(C₆F₅)₄, tetrakis(3,5-bis(trifluoromethyl)phenyl)borate acid, p-toluenesulfonic acid, HB(CF₃)₄ and cyclopentadiene penta-substituted with electron withdrawing groups such as cyclopenta-1,3-diene-1,2,3,4,5-pentacarbonitrile. Other photoacid generators include trihalomethyl compounds and also photosensitive derivatives of trihalomethyl heterocylic compounds which can generate a hydrogen halide such as HBr or HCl.

### Photoresist Compositions Comprising a Thiol Derivative and the Process of Using These to Produce Anisotropically Etched Metal Substrate

### Photoresist Compositions

In one of its aspects, this invention is a photoresist composition comprising,
a thiol derivative where the thiol moiety is attached to an SP2 carbon which is part of a ring which has structures (H1), (H2) (H3), or (H4), and where this thiol derivative is present in a range of about 0.5 wt. % to about 3 wt. % of total solids, wherein
in said structure (H1), Xt is selected from the group consisting of N(Rt₃), C(Rt₁)(Rt₂), O, S, Se, and Te;
in said structure (H2), Y is selected from the group consisting of C(Rt₃) and N;
in said structure (H3), Z is selected from the group consisting of C(Rt₃) and N; and
in said structure (H4), where Arene is selected from an unsubstituted phenyl, a substituted phenyl, an unsubstituted polycyclic arene moiety and a substituted polycyclic arene moiety, Rt₁, Rt₂, and Rt₃ are independently selected from the group consisting of H, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms,
Rt₄ is independently selected from the group consisting of H, OH, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms.

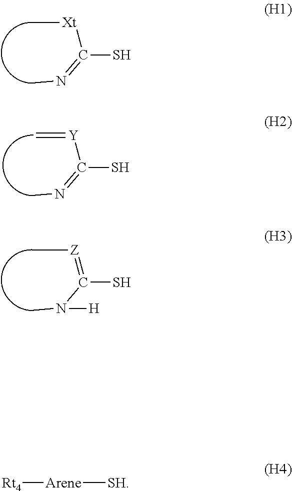

In one aspect of this invention said thiol derivative is a heterocyclic thiol chosen from the above general structures (H1), (H2) or (H3), or tautomers thereof, wherein such heterocyclic thiols may be chosen, without limitation from the following compounds (H5) to (H23) in unsubstituted or substituted form:

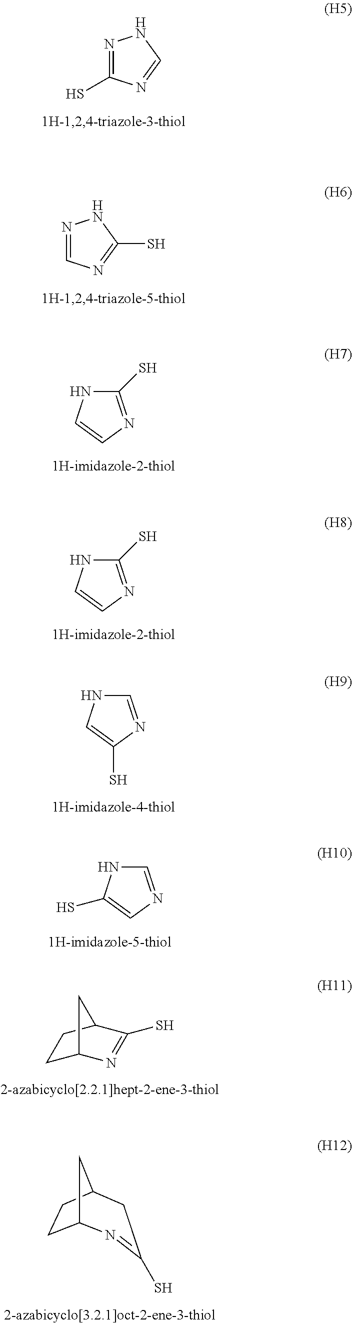

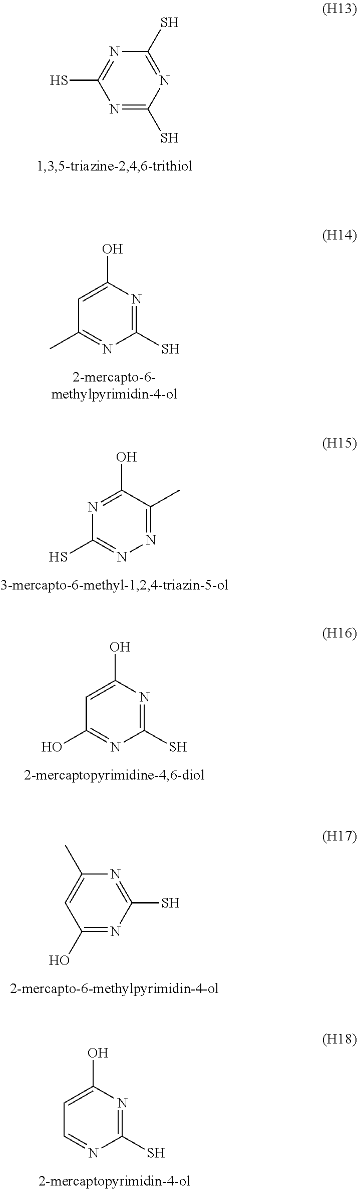

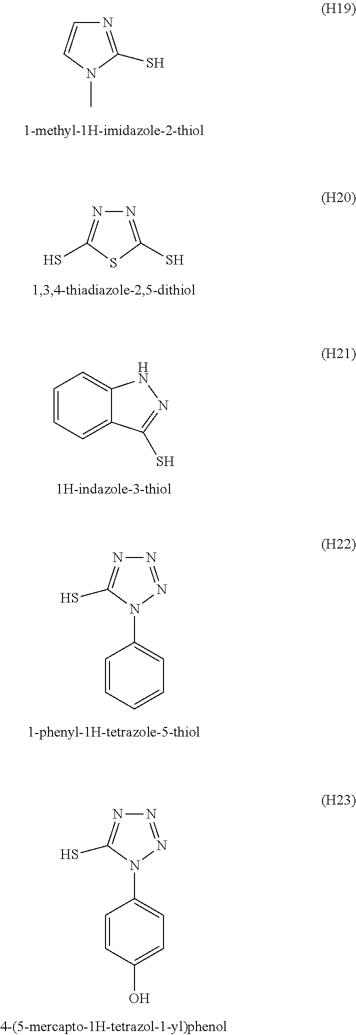

In another aspect of the embodiment wherein said inventive composition comprises at least one heterocyclic thiol having general structures (H1), (H2) or (H3), or tautomers thereof, such heterocyclic thiols may be chosen from thiouracil derivatives such as 2-thiouracil. These include, without limitation, 5-methyl-2-thiouracil, 5,6-dimethyl-2-thiouracil, 6-ethyl-5-methyl-2-thiouracil, 6-methyl-5-n-propyl-2-thiouracil, 5-ethyl-2-thioracil, 5-n-propyl-2-thiouracil, 5-n-butyl-2-thiouracil, 5-n-hexyl-2-thiouracil, 5-n-butyl-6-ethyl-2-thiouracil, 5-hydroxy-2-thiouracil, 5,6-dihydroxy-2-thiouracil, 5-hydroxy-6-n-propyl-2-thiouracil, 5-methoxy-2-thiouracil, 5-n-butoxy-2-thiouracil, 5-methoxy-6-n-propyl-2-thiouracil, 5-bromo-2-thiouracil, 5-chloro-2-thiouracil, 5-fluoro-2-thiouracil, 5-amino-2-thiouracil, 5-amino-6-methyl-2-thiouracil, 5-amino-6-phenyl-2-thiouracil, 5,6-diamino-2-thiouracil, 5-allyl-2-thiouracil, 5-allyl-3-ethyl-2-thiouracil, 5-allyl-6-phenyl-2-thiouracil, 5-benzyl-2-thiouracil, 5-benzyl-6-methyl-2-thiouracil, 5-acetamido-2-thiouracil, 6-methyl-5-nitro-2-thiouracil, 6-amino-2-thiouracil, 6-amino-5-methyl-2-thiouracil, 6-amino-5-n-propyl-2-thiouracil, 6-bromo-2-thiouracil, 6-chloro-2-thiouracil, 6-fluoro-2-thiouracil, 6-bromo-5-methyl-2-thiouracil, 6-hydroxy-2-thiouracil, 6-acetamido-2-thiouracil, 6-n-octyl-2-thiouracil, 6-dodecyl-2-thiouracil, 6-tetradodecyl-2-thiouracil, 6-hexadecyl-2-thiouracil, 6-(2-hydroxyethyl)-2-thiouracil, 6-(3-isopropyloctyl)-5-methyl-2-thiouracil, 6-(m-nitrophenyl)-2-thiouracil, 6-(m-nitrophenyl)-5-n-propyl-2-thiouracil, 6-a-naphthyl-2-thiouracil, 6-α-naphthyl-5-tert-butyl-2-thiouracil, 6-(p-chlorophenyl)-2-thiouracil, 6-(p-chlorophenyl)-2-ethyl-2-thiouracil, 5-ethyl-6-eicosyl-2-thiouracil, 6-acetamido-5-ethyl-2-thiouracil, 6-eicosyl-5-allyl-2-thiouracil, 5-amino-6-phenyl-2-thiouracil, 5-amino-6-(p-chlorophenyl)-2-thiouracil, 5-methoxy-6-phenyl-2-thiouracil, 5-ethyl-6-(3,3-dimethyloctyl)-2-thiouracil, 6-(2-bromoethyl)-2-thiouracil, 1-phenyl-1H-tetrazole-5-thiol, 4-(5-mercapto-1H-tetrazol-1-yl) phenol, tautomers thereof and combinations thereof.

In another embodiment wherein said inventive composition comprises at least one heterocyclic thiol chosen from the above general structures (H1), (H2) or (H3), or tautomers thereof, such heterocyclic thiols may be selected from the group consisting of unsubstituted triazole thiol, substituted triazole thiol, unsubstituted imidazole thiol, substituted imidazole thiol, substituted triazine thiol, unsubstituted triazine thiol, a substituted mercapto pyrimidine, unsubstituted mercapto pyrimidine, a substituted thiadiazole-thiol, unsubstituted thiadiazole-thiol, substituted indazole thiol, unsubstituted indazole thiol, tautomers thereof, and combinations thereof.

In the photoresist composition described herein, said thiol derivatives of structure (H1), (H2), (H3) or (H4) are present at a loading from about 0.6 wt. % to about 3 wt. % of total solids. In another aspect of this embodiment said thiol derivative is present at a loading from about 0.7 wt. % to about 3 wt. % of total solids. In another aspect of this embodiment, said thiol derivative is present at a loading from about 0.8 wt. % to about 3 wt. % of total solids. In another aspect of this embodiment,. said thiol derivative is present at a loading from about 0.9 wt. % to about 3 wt. % of total solids. In another aspect of this embodiment, said thiol derivative is present at a loading from about 1 wt. % to about 3 wt. % of total solids.

In another aspect of this photoresist composition, described herein, said thiol derivative of structure (H1), (H2), (H3) or (H4) is present at a loading from, from about 0.5 wt. % to about 2.5 wt. % of total solids. In another aspect of this embodiment, said thiol derivative is present at a loading from about 0.5 wt. % to about 2.0 wt. % of total solids. In another aspect of this embodiment, said thiol derivative is present at a loading from about 0.5 wt. % to about 1.5 wt. % of total solids. In another aspect of this embodiment, said thiol derivative is present at a loading from about 0.5 wt. % to about 1.4 wt. % of total solids. In another aspect of this embodiment, said thiol derivative is present at a loading from about 0.5 wt. % to about 1.3 wt. % of total solids. In another aspect of this embodiment, said thiol derivative is present at a loading from about 0.5 wt. % to about 1.2 wt. % of total solids. In another aspect of this embodiment, said thiol derivative is present at a loading from about 0.5 wt. % to about 1.1 wt. % of total solids. In another aspect of this embodiment, said thiol derivative is present at a loading from about 0.5 wt. % to about 1 wt. % of total solids.

In another aspect of this photoresist composition, described herein, said thiol derivative, has structure (H2).

In another aspect of this photoresist composition, described herein, said thiol derivative has structure (H3).

In another aspect of this photoresist composition, described herein, said thiol derivative said thiol derivative has structure (H1).

In one aspect of this photoresist composition, described herein, wherein said thiol derivative has structure (H1), Xt is N(Rt₃).

In one aspect of this photoresist composition, described herein, wherein said thiol derivative has structure (H1), and Xt is N(Rt₃), it has structure (H1-A), wherein X₁ is N, X₂ and X₃ are individually selected from the group consisting of N, and C (Rt₃) and Rx₁, Rx₂, Rx₃, Rx₄, and Rx₅ are individually selected from the group consisting of H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4), where in C(Rt₃), Rt₃ is independently selected from the group consisting of H, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms.

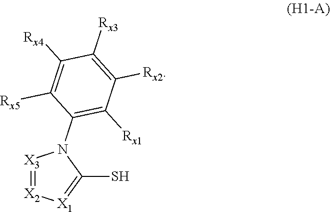

In one aspect of this photoresist composition, described herein, wherein said thiol derivative has structure (H1), and Xt is N(Rt₃), it has structure (H1-B), wherein Rx, is selected from the group consisting of H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4). Rc₂ is selected from H and a C-1 to C-8 alkyl, Rc₁ is selected from H and a C-1 to C-8 alkyl.

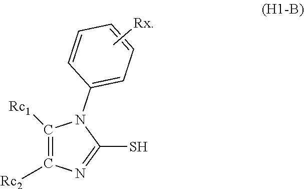

In one aspect of this photoresist composition, described herein, wherein said thiol derivative has structure (H1), and Xt is N(Rt₃), it has structure (H1-C), wherein Rc₂ is selected from H and a C-1 to C-8 alkyl, and Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4),

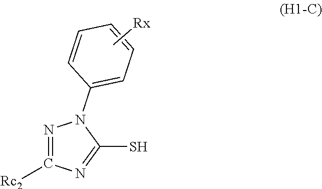

In one aspect of this photoresist composition, described herein, wherein said thiol derivative has structure (H1), and Xt is N(Rt₃), it has structure (H1-D), wherein Rc₁ is selected from H and a C-1 to C-8 alkyl, and Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4).

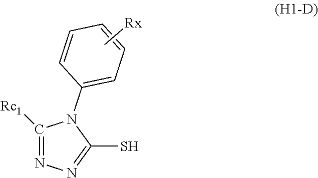

In one aspect of this photoresist composition, described herein, wherein said thiol derivative has structure (H1), and Xt is N(Rt₃), it has structure (H1-E), wherein Rx is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4).

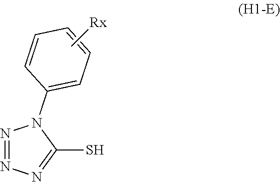

In one aspect of this photoresist composition, described herein, wherein said thiol derivative has structure (H1), and Xt is N(Rt₃), it has structure (H1-EA), wherein Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4).

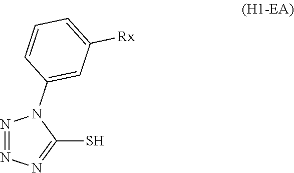

In one aspect of this photoresist composition, described herein, wherein said thiol derivative has structure (H1), and Xt is N(Rt₃), it has structure (H1-EB), wherein Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4),

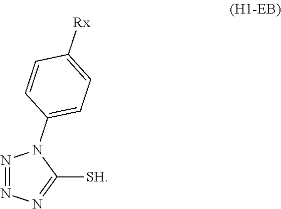

In one aspect of this photoresist composition, described herein, wherein said thiol derivative has structure (H1), and Xt is N(Rt₃), it has structure (H1-EC), or structure (H1-ED). In one aspect of this embodiment, it has structure (H1-EC). In another aspect of this embodiment, it has structure (HI-ED).

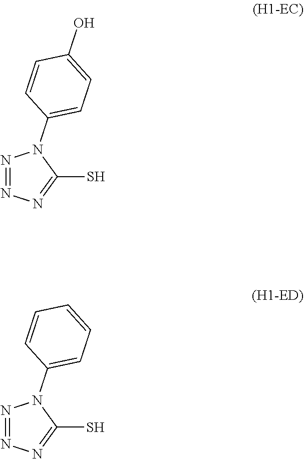 [SMILES: Oc1ccc(-n2nnnc2S)cc1 ; Sc1nnnn1-c1ccccc1]

In one aspect of this photoresist composition, described herein, wherein said thiol derivative has structure (H1), and Xt is N(Rt₃), it has structure (H1-EE).

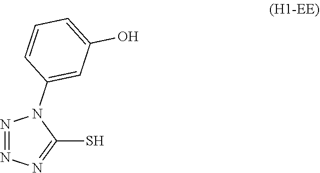 [SMILES: Oc1cccc(-n2nnnc2S)c1]

In one aspect of this photoresist composition, described herein, wherein said thiol derivative has structure (H4), where Arene is selected from an unsubstituted phenyl, a substituted phenyl, an unsubstituted polycyclic arene moiety and a substituted polycyclic arene moiety. In one aspect of this embodiment, said arene is a substituted or unsubstituted polycyclic arene. In another aspect of this embodiment, said Arene is selected from naphthalene, anthracene and pyrene. In yet another aspect of this embodiment, said Arene is a substituted or unsubstituted phenyl. In one aspect of this embodiment said arene is phenyl.

In one aspect of this photoresist composition, described herein, wherein said thiol derivative has structure (H4), it more specifically has structure (H4-A), wherein R_{H4a}, R_{H4b}, R_{H4c}, R_{H4d}, R_{H4e}, are individually selected from H, OH, a halide, a C-1 to C-8 alkyl, an unsubstituted aromatic group having 6 to 20 carbon atoms, an aromatic group having 6 to 20 carbon atoms substituted with at least one hydroxy, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4.

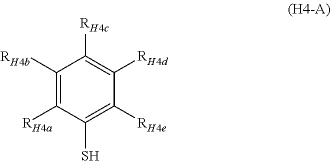

In one aspect of this photoresist composition, described herein, wherein said thiol derivative has structure (H4), it more specifically has structure (H4-B), wherein R_{H4} is selected from H, OH, a halide, a C-1 to C-8 alkyl, an unsubstituted aromatic group having 6 to 20 carbon atoms, an aromatic group having 6 to 20 carbon atoms substituted with at least one hydroxy, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4.

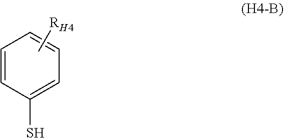

In one aspect of this photoresist composition, described herein, wherein said thiol derivative has structure (H4), it more specifically has structure (H4-C), wherein R_{4H} is selected from H, OH, a halide, a C-1 to C-8 alkyl, an unsubstituted aromatic group having 6 to 20 carbon atoms, an aromatic group having 6 to 20 carbon atoms substituted with at least one hydroxy, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4.

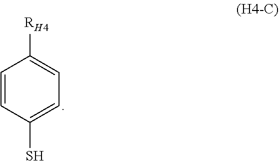

In one aspect of this photoresist composition, described herein, wherein said thiol derivative has structure (H4), it more specifically has structure (H4-D), wherein Rx₁ is selected from H, OH, a halide, a C-1 to C-8 alkyl, an unsubstituted aromatic group having 6 to 20 carbon atoms, an aromatic group having 6 to 20 carbon atoms substituted with at least one hydroxy, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4.

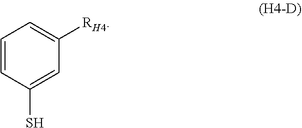

In one aspect of this photoresist composition, described herein, wherein said thiol derivative has structure (H4), it more specifically has structure (H4-E),

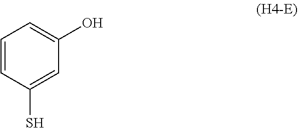

In one aspect of this photoresist composition, described herein, wherein said thiol derivative has structure (H4), it more specifically it has structure (H4-F).

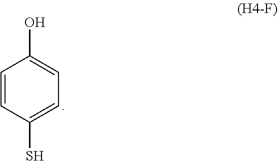

In one aspect of this photoresist composition, it is a positive non-chemically amplified photoresist, developable in aqueous base.

In one aspect of this photoresist composition, it is a positive non-chemically amplified photoresist, developable in aqueous base, comprising,
at least one Novolak type resin which is soluble in about 0.26 N TMAH,
at least one DNQ PAC component and
an organic spin casting solvent.

In one aspect of this photoresist composition, it is a positive non-chemically amplified photoresist, developable in aqueous base, comprising,
at least one Novolak type resin which is soluble in about 0.26 N TMAH,
at least one DNQ PAC component,
a photo-bleachable dye and
an organic spin casting solvent.

In one aspect of this photoresist composition, it is a positive non-chemically amplified photoresist, developable in aqueous base, comprising,
at least one Novolak type resin which is soluble in about 0.26 N TMAH,
at least one DNQ PAC component,
2000 ppm to 14,000 ppm of a surfactant, and
an organic spin casting solvent.

In one aspect of this photoresist composition, it is a positive non-chemically amplified photoresist, developable in aqueous base, comprising,
at least one meth(acrylate) copolymer which comprises repeat units derived from (meth)acrylic acid, and which is solution in about 0.26 N TMAH,
at least one Novolak type resin which is soluble in about 0.26 N TMAH,
at least one DNQ PAC component, and
an organic spin casting solvent.

In one aspect of this photoresist composition, it is a positive chemically amplified photoresist composition developable in aqueous base.

In one aspect of this photoresist composition, it is a positive chemically amplified photoresist composition developable in aqueous base, comprising,
at least one photoacid generator,
at least one polymer, comprising one or more (meth)acrylate repeat units and further comprising one or more repeat units with at least one acid cleavable group,
an organic spin casting solvent, further wherein,
   said composition does not comprise any Novolak resin.

In one aspect of this photoresist composition, it is a positive chemically amplified photoresist composition developable in aqueous base, comprising,
at least one photoacid generator,
at least one polymer, comprising one or more (meth)acrylate repeat units and further comprising one or more repeat units with at least one acid cleavable group,
at least one Novolak type resin and
an organic spin casting solvent.

In one aspect of this photoresist composition, it is a positive chemically amplified photoresist composition developable in aqueous base, comprising,
at least one photoacid generator,
at least one DNQ PAC component,
at least one Novolak resin,
at least one polymer, comprising one or more (meth)acrylate repeat units and further comprising one or more repeat units with at least one acid cleavable group,
an organic spin casting solvent.

In one aspect of this photoresist composition, it is a positive chemically amplified photoresist composition developable in aqueous base, comprising,
at least one photoacid generator,
at least one polymer, comprising one or more (meth)acrylate repeat units and further comprising one or more repeat units with at least one acid cleavable group,
a photo bleachable dye,
an organic spin casting solvent.

In one aspect of this photoresist composition, it is a positive chemically amplified photoresist composition developable in aqueous base, comprising,
at least one polymer comprising one or more (meth)acrylate repeat units and further comprising one or more repeat units with a at least one acid labile group,
at least one Novolak type resin which is soluble in about 0.26 N TMAH,
at least one photoacid generator (PAG), and
an organic spin casting solvent.

In one aspect of this photoresist composition, it is a positive chemically amplified (meth)acrylate type photoresist, developable in aqueous base, comprising,
at least one (meth)acrylate copolymer comprising a (meth)acrylic acid derived repeat unit, whose carboxylic acid is functionalized with an acid labile group, repeat units derived from at least one of styrene and benzyl (meth)acrylate, wherein said polymer becomes soluble in about 0.26 N TMAH, if the acid labile group is cleaved by photogenerated acid from the PAG,
at least one PAG,
an organic spin casting solvent.

In one aspect of this photoresist composition, said photoresist composition is a positive chemically amplified (meth)acrylate type photoresist, developable in aqueous base, comprising,
at least one (meth)acrylate copolymer comprising a (meth)acrylic acid derived repeat unit, whose carboxylic acid is functionalized with an acid labile group, repeat units derived from at least one of styrene and benzyl (meth)acrylate, wherein said polymer becomes soluble in 0.26 N TMAH, if the acid labile group is cleaved by photogenerated acid from the PAG,
at least one Novolak type resin which is soluble in about 0.26 N TMAH,
at least one PAG, and
an organic spin casting solvent.

In one aspect of this photoresist composition, it is a positive chemically amplified photoresist, developable in aqueous base, comprising,
a component comprising a reaction product formed in the absence of an acid catalyst between (i) a Novolak polymer, (ii) a polymer comprising substituted or unsubstituted hydroxystyrene and acrylate, methacrylate or a mixture of acrylate and methacrylate, the acrylate and/or methacrylate being protected by an acid labile group that requires a high activation energy for deblocking, and (iii) a compound selected from a vinyl ether and an unsubstituted or substituted, unsaturated heteroalicyclic;
at least one PAG,
an organic spin casting solvent.

In one aspect of this photoresist composition, it is a positive chemically amplified photoresist, developable in aqueous base, comprising,
a component comprising a reaction product formed in the absence of an acid catalyst between (i) a Novolak polymer, (ii) a polymer comprising substituted or unsubstituted hydroxystyrene and acrylate, methacrylate or a mixture of acrylate and methacrylate, the acrylate and/or methacrylate being protected by an acid labile group that requires a high activation energy for deblocking, and (iii) a compound selected from a vinyl ether and an unsubstituted or substituted, unsaturated heteroalicyclic;
at least one polymer comprising repeat units derived from 4-hydroxystyrene, repeat units derived from an acetal protected 4-hydrostyrene, and a repeat unit derived from a (meth)acrylic acid protected with a high energy protecting group,
at least one PAG,
an organic spin casting solvent.

In one aspect of this photoresist composition, it is a is a negative non-chemically amplified photoresist which is developable in aqueous base.

In one aspect of this photoresist composition, it is a is a negative non-chemically amplified photoresist which is developable in aqueous base, comprising,
at least one alkali-soluble polymer, where the polymer comprises at least one unit of structure (INR),

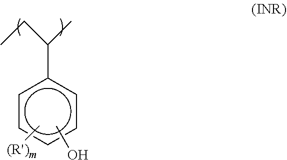

where, R′ is selected independently from hydrogen, (C₁-C₄)alkyl, chlorine and bromine, and m is an integer from 1 to 4;
at least one monomer of structure (IINR),

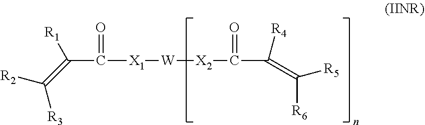

where, W is a multivalent linking group, R₁ to R₆ are independently selected from hydrogen, hydroxy, (C₁-C₂₀) alkyl and chlorine, X₁ and X₂ are independently oxygen or N-R₇, where R₇ is hydrogen or (C₁-C₂₀) alkyl, and n is an integer equal to or greater than 1; and,
at least one radical photoinitiator and
an organic spin casting solvent.

In one aspect of this photoresist composition, it is a is a negative non-chemically amplified photoresist which is developable in aqueous base, comprising,
at least one Novolak type resin which is soluble in about 0.26 N TMAH,
at least one radical photoinitiator,
at least one (meth)acrylate crosslinker and
an organic spin casting solvent.

In one aspect of this photoresist composition, it is a negative non-chemically amplified (meth)acrylate type photoresist, developable in aqueous base, comprising
at least one (meth)acrylate polymer comprising a (meth)acrylic acid derived repeat unit, a repeat unit derived from at least one of styrene and benzyl (meth)acrylate, which is soluble in about 0.26 N TMAH,
at least one radical photoinitiator,
at least one (meth)acrylate crosslinker and
an organic spin casting solvent.

In one aspect of this photoresist composition, it is a negative chemically amplified photoresist developable in aqueous base.

In one aspect of this photoresist composition, it is a negative chemically amplified photoresist developable in aqueous base, comprising,
at least one phenolic film-forming polymeric binder resin having ring bonded hydroxyl groups, selected from a Novolak resin, a hydroxystyrene copolymer, or mixtures thereof which is soluble in 0.26 N TMAH
at least one PAG,
a crosslinking agent that forms a carbonium ion upon exposure to acid photogenerated by the PAG and which comprises an etherified aminoplast polymer or oligomer and
an organic spin casting solvent.

### Processs of Using Photoresist Compositions Comprising a Thiol Derivative to Produce an Anisotropically Etched Metal Substrate

Another aspect of this invention is a process of patterning a metal substrate to produce anisotropically etched metal substrate, comprising
i) cleaning a metal substrate overlying a semiconductor with a 1 to 5 wt. % aqueous solution of a tri or dicarboxylic acid, followed by distilled water rinse to obtain a cleaned metal substrate,
ii) spin drying the cleaned metal substrate,
iii) applying the composition of the invention on the cleaned and dry metal substrate to obtain a photoresist coating,
iv) baking the photoresist coating to remove solvent at a temperature between 90 and 120° C.,
v) patterning the photoresist with UV radiation followed by development with an aqueous base developer, to obtain a patterned of photoresist etch barrier overlying the metal substrate,
vi) using the patterned photoresist as a etch barrier, treat with a wet acidic chemical etchant to produce an anisotropically etched metal pattern, overlaid with the patterned photoresist etch barrier,
vii) remove the overlying patterned photoresist etch barrier with a stripper, producing an anisotropically etched metal substrate.

In another aspect of the process of patterning a metal substrate to produce anisotropically etched metal substrate, the metal substrate is a metal substrate overlying a semiconductor substrate and step vii) produces an anisotropically etched metal substrate overlying a semiconductor substrate.

In another aspect of this process said metal substrate, is selected from a Copper substrate, an Aluminum substrate, an aluminum alloy substrate, silver, gold, nickel, and tungsten. In another aspect of this embodiment the metal substrate is a copper substrate. In another aspect of this embodiment the metal substrate is aluminum. In another aspect of this embodiment the metal substrate is an aluminum alloy. In another aspect of this embodiment the metal substrate is a silver substrate. In another aspect of this embodiment the metal substrate is a gold substrate. In another aspect of this embodiment the metal substrate is a nickel substrate. In another aspect of this embodiment the metal substrate is a tungsten substrate.

### Details on Suitable Other Components for Photoresist Formulations

### Novolak Components

In the non-chemically amplified and chemically amplified photoresist formulations, described herein, which contain a Novolak resin this component is a Novolak resin which is soluble at 23° C. in an aqueous developer such as 0.26 N TMAH. This Novolak resin may comprise repeat units of structure (N) where Ra1, Ra2 and Ra3 are each independently (i) a hydrogen, (ii) an unsubstituted C-1 to C-4 alkyl, (iii) a substituted C-1 to C-4 alkyl, (iv) an unsubstituted-X-Phenol group where X is —O—, —C(CH₃)₂—, —CH₂—, —(C═O)— or —SO₂— or (v) a substituted -X-Phenol group where X is —O—, —C(CH₃)₂—, —CH₂—, —C(═O)— or —SO₂—. In another aspect of this embodiment, Ra1 and Ra2 are each hydrogen and Ra3 is an unsubstituted C-1 to C-4 alkyl. In yet another aspect of this embodiment, Ra1 and Ra2 are each hydrogen and Ra3 is —CH₃. In still another aspect of this embodiment, the repeat unit (N) has the structure (NA). In another aspect of this embodiment, Novolak-based resin component further comprises one or more of repeat units of structure (NB) where (i) Ra1, Ra2 and Ra3 are each independently a hydrogen, an unsubstituted C-1 to C-4 alkyl or a substituted C-1 to C-4 alkyl, (ii) X is —O—, —C(CH₃)₂—, —CH₂—, —C(═O)—, or —SO₂— and (iii) each Ra4 is independently a hydrogen, an unsubstituted C-1 to C-4 alkyl or a substituted C-1 to C-4 alkyl, in a specific aspect of this embodiment structure (NB) has the more specific structure (NC).

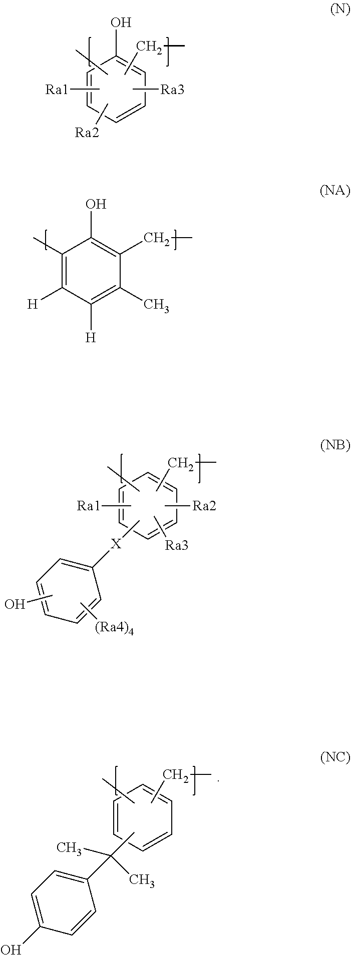

### DNQ PAC Component

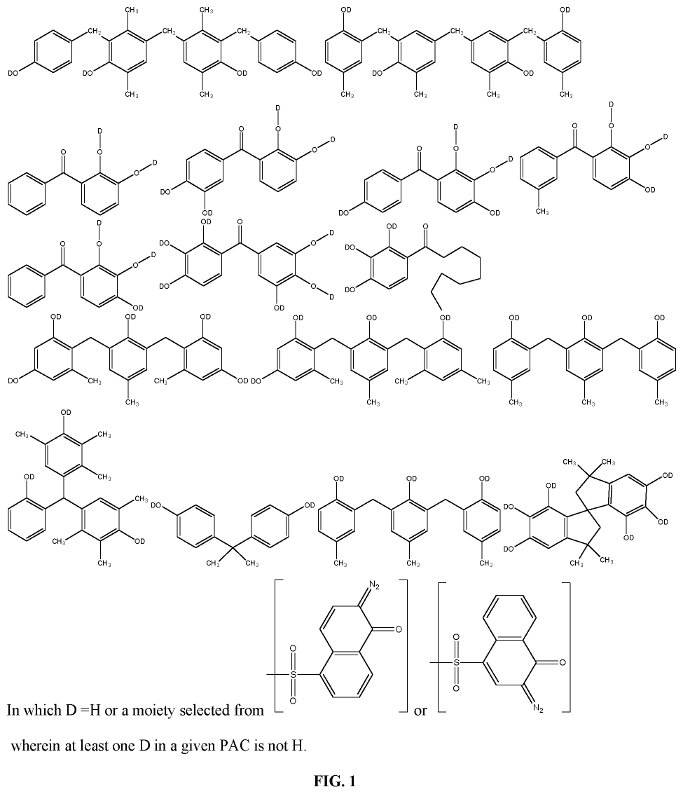

In other embodiments of the photoresist compositions, described herein, wherein a DNQ PAC component is present, it may be derived from a 1,2-diazonaphthoquinone-5-sulfonate compound or a 1,2-diazonaphthoquinone-4-sulfonate compound. FIG. 1 shows non-limiting examples of these types of DNQ PAC's, which may be used as free PAC component; wherein, in this FIG., the moiety D is H or a moiety selected from structure (DNQa) and structure (DNQb), wherein in each compound depicted in FIG. 1 at least one D is either a moiety of structure (DNQa) or (DNQb).

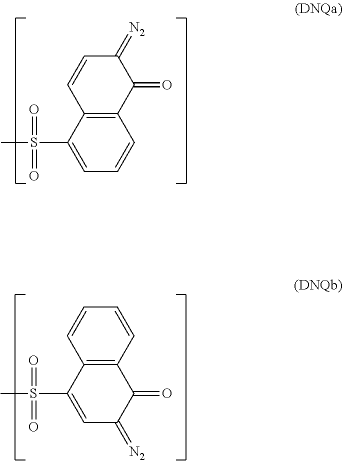

In other embodiments of the photoresist compositions, described herein, this DNQ PAC component is either a single DNQ PAC compound or a mixture of DNQ PAC compounds having structure (DNQc), wherein D_{1c}, D_{2c}, D_{3c}, and D_{4c} are individually selected from H or a moiety having structure (DNQa), and further wherein at least one of D_{1c}, D_{2c}, D_{3c} or D_{4c} is a moiety having structure (DNQa).

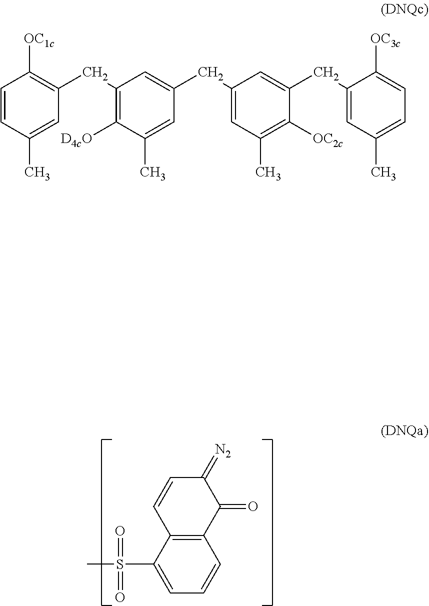

In other embodiments of the photoresist compositions, described herein, wherein it comprises a DNQ PAC component, this DNQ PAC component is either a single DNQ PAC compound or a mixture of PAC compounds having structure (DNQc), wherein D_{1c}, D_{2c}, D_{3c} and D_{4c} are individually selected from Hor a moiety having structure (DNQb), and further wherein at least one of D_{1c}, D_{2c}, D_{3c} or D_{4c} is a moiety having structure (DNQb).

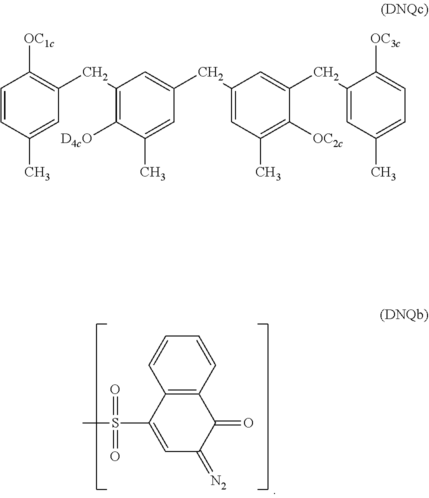

In other embodiments of the photoresist compositions, described herein, wherein it comprises a free PAC component, this PAC component is either a single PAC compound or a mixture of PAC compounds having structure (DNQd), wherein D_{1d}, D_{2d}, D_{3d}, and D_{4d} are individually selected from H or a moiety having structure (DNQa), and further wherein at least one of D_{1d}, D_{2d}, D_{3d} or D_{4d} is a moiety having structure (DNQa).

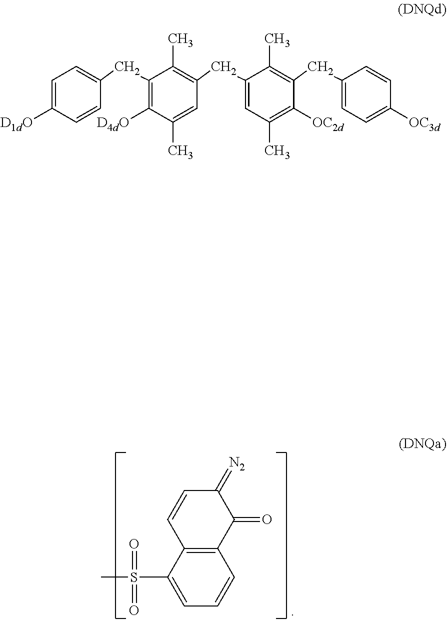

In other embodiments of the photoresist compositions, described herein, wherein it comprises a DNQ PAC component, this DNQ PAC component is either a single DNQ PAC compound or a mixture of DNQ PAC compounds having structure (DNQd), wherein D_{1d}, D_{2d}, D_{3d}, and D_{4d} are individually selected from H or a moiety having structure (DNQb), and further wherein at least one of D_{1d}, D_{2d}, D_{3d} or D_{4d} is a moiety having structure (DNQb).

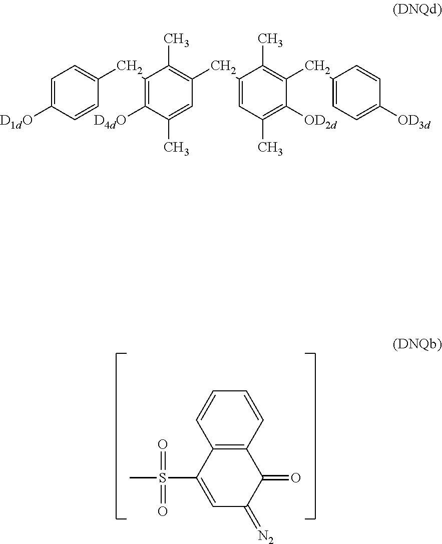

In other embodiments of the photoresist compositions, described herein, wherein it comprises a DNQ PAC component, this DNQ PAC component is either a single DNQ PAC compound or a mixture of PAC compounds having structure (DNQe), wherein D₁ₑ, D₂ₑ, and D₃ₑ are individually selected from H or a moiety having structure (DNQa), and further wherein at least one of D₁ₑ, D₂ₑ, or D₃ₑ is a moiety having structure (DNQa).

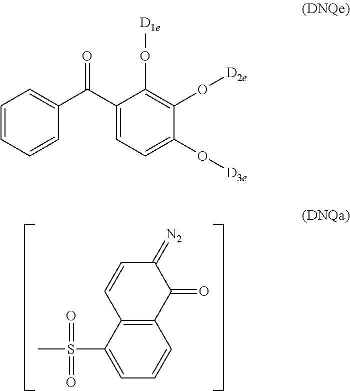

In other embodiments of the photoresist compositions, described herein, wherein it comprises a free PAC component, this PAC component is either a single PAC compound or a mixture of PAC compounds having structure (DNQe), wherein D₁ₑ, D₂ₑ, and D₃ₑ are individually selected from H or a moiety having structure (DNQb), and further wherein at least one of D₁ₑ, D₂ₑ, or D₃ₑ is a moiety having structure (DNQb).

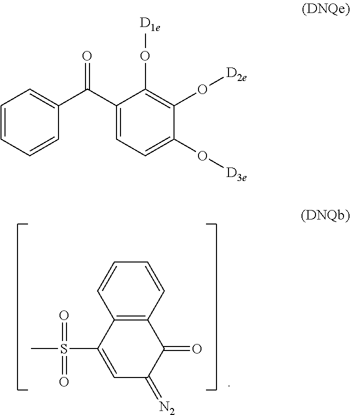

### Photoacid Generator (PAG) Component

In the chemically amplified photoresist formulations, described herein, which contain a PAG component this component is a material sensitive to radiation such as UV radiation (e.g. broadband, i-line, g-line, 248 nm 193 nm and EUV), which upon exposure to this radiation release an acid (a.k.a. photo-acid) which can cleave acid labile group such as tert-alkyl esters, or acetals releasing a base solubilizing group in a resin employed in a positive chemically amplified photoresist making these exposed regions base soluble generating a positive image, or alternatively in negative chemically amplified photoresist cleave a group to generate a carbocation which can react with the photoresist resin to crosslink a base soluble resin making it insoluble in the exposed region generating a negative image. This photo-acid may be a sulfonic acid, HCl, HBr, HAsF₆, and the like. It includes as non-limiting examples onium salts and other photosensitive compounds as known in the art that can photochemically generate c strong acids such as alkylsulfonic acid, arylsulfonic acid, HAsF₆, HSbF₆, HBF₄, HPF₆, CF₃SO₃H, HC(SO₂CF₃)₂, HC(SO₂CF₃)₃, HN(SO₂CF₃)₂, HB(C₆H₅)₄, HB(C₆F₅)₄, tetrakis(3,5-bis(trifluoromethyl)phenyl) borate acid, p-toluenesulfonic acid, HB(CF₃)₄ and cyclopentadiene penta-substituted with electron withdrawing groups such as cyclopenta-1,3-diene-1,2,3,4,5-pentacarbonitrile. Other photoacid generators include trihalomethyl compounds and photosensitive derivatives of trihalomethyl heterocylic compounds which can generate a hydrogen halide such as HBr or HCl. The PAG may be an aromatic imide N-oxysulfonate derivative of an organic sulfonic acid, an aromatic sulfonium salt of an organic sulfonic acid, a trihalotriazine derivative or a mixture thereof.

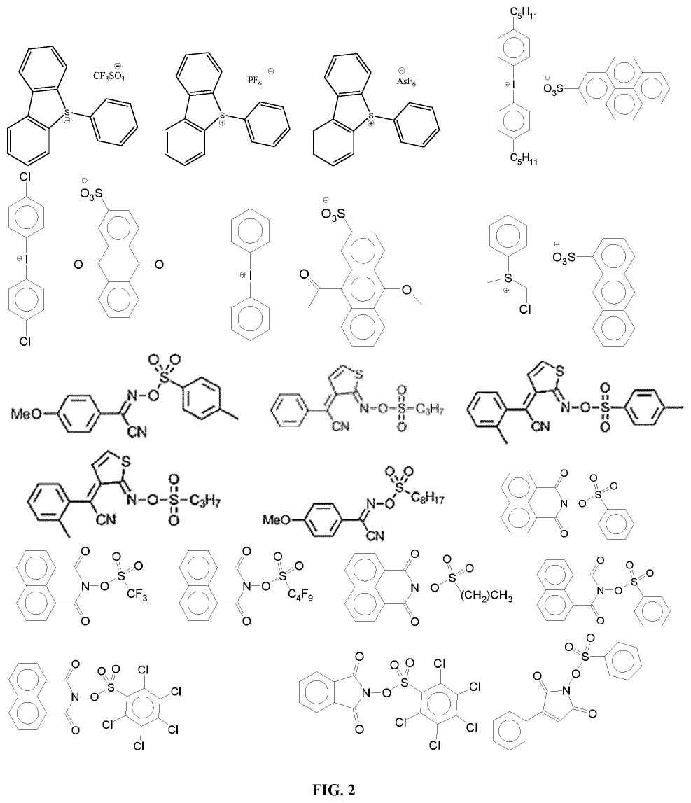

FIG. 2 Shows non-limiting examples of photoacid generators which generate sulfonic, and other strong acids.

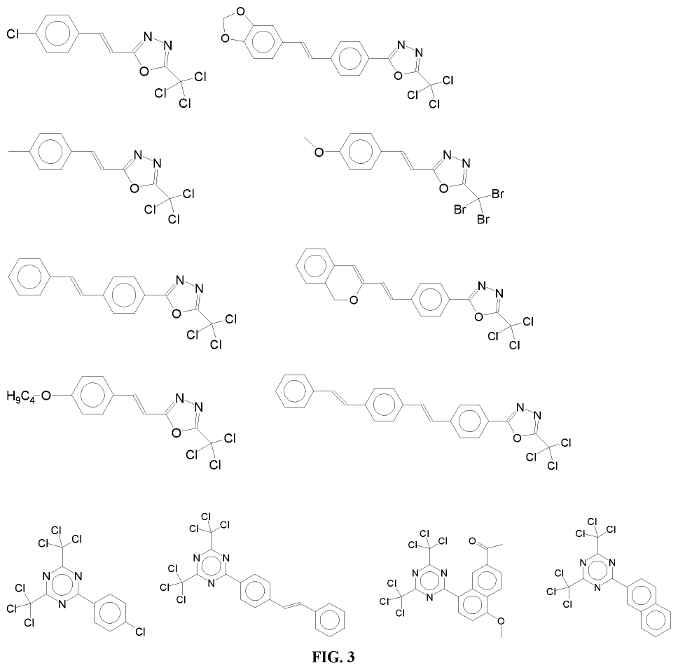

FIG. 3 Shows non-limiting examples of photoacid generators which generate either HCl or HBr.

In one aspect of this embodiment, it has structure (P) wherein R₁ₚ is a fluoroalkyl moiety and R₂ₚ is H, an alkyl, an oxyalkyl, a thioalkyl, or an aryl moiety. Alternatively, this PAG may have structure (PA) wherein R₃ₚ is a fluoroalkyl, an alkyl or an aryl moiety and R₄ₚ is H, an alkyl, an oxyalkyl, a thioalkyl, or an aryl moiety. Another aspect of this inventive composition, as described herein, is where component d), the photo acid generator (PAG) component comprises 1,3-dioxo-1H-benzo[de]isoquinolin-2(3H)-yl trifluoromethanesulfonate (NIT PAG).

This PAG component, as described herein, may range from about 0.1 wt. % to about 2 wt. % of total wt. % solids.

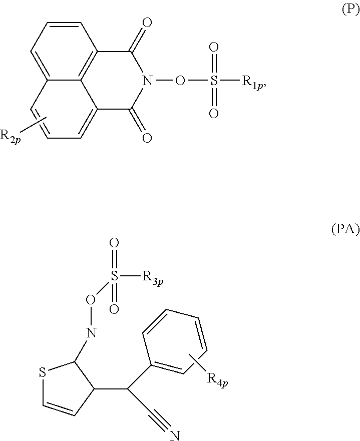

### Base additive Components

In the chemically amplified photoresist formulations, described herein, which contain a PAG, an optional component which may be added is a base component to moderate acid diffusion in the exposed region of the photoresist resulting from the photo-acid. This base component may be any base component sufficiently basic to neutralize the photo-acid. Another aspect of this inventive composition, as described herein, is component e), the base additive, where this base additive can include, but is not limited to a basic material or combination of materials such as an amine compound or a mixture of amine compounds having a boiling point above 100° C., at atmospheric pressure, and a pKₐ of at least 1. Such acid quenchers include, but are not limited to, amine compounds having structures (BIa), (BIb), (BIc), (BId), (BIe), (BIf), (BIg), (BIh), (BIi) (BIj), (BIk) and (BIl) or a mixture of compounds from this group; wherein R_{b1} is C-1 to C-20 saturated alkyl chain or a C-2 to C-20 unsaturated alkyl chain; R_{b2}, R_{b3}, R_{b4}, R_{b5}, R_{b6}, R_{b7}, R_{b8}, R_{b9}, R_{b10}, R_{b11}, R_{b12} and R_{b13}, are independently selected from the group of H, and a C-1 to C-20 alkyl.

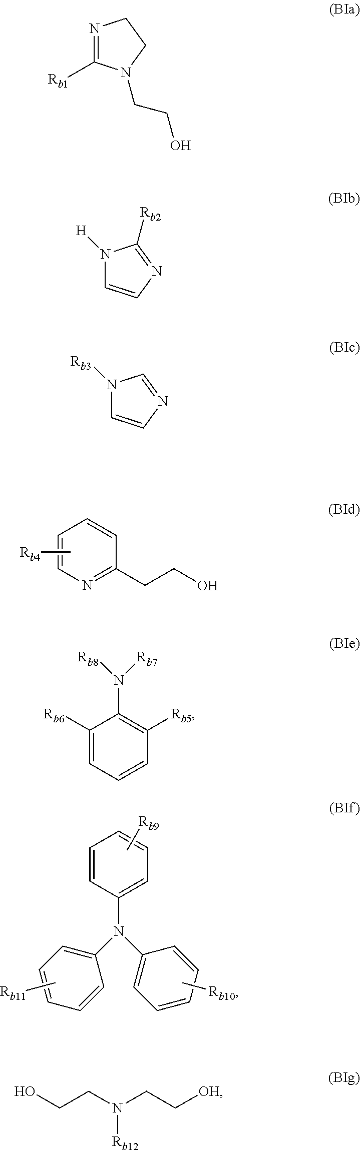

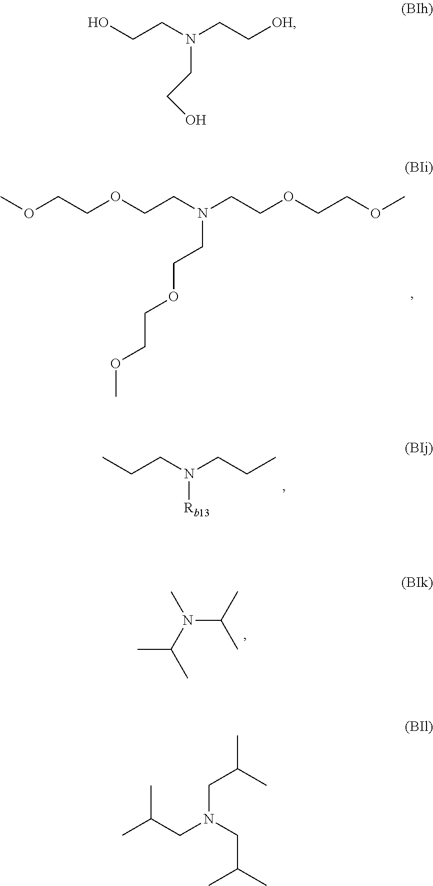

This base additive component can be chosen from, but is not limited to, a basic material or combination of materials which are tetraalkylammonium or trialkylammonium salts of a dicarboxylic acid or mixtures of these. Specific non limiting examples are mono(tetraalkyl ammonium) of dicarboxylic acid, di(tetraalkyl ammonium) salts of dicarboxylic acid, mono(trialkyl ammonium) of dicarboxylic acid, or di(trialkyl ammonium) salts of dicarboxylic acid. Non-limiting examples of suitable dicarboxylic acid for these salts are oxalic acid, maleic acid, malonic acid, fumaric acid, phthalic acid, and the like. Structures (BIma), (BImb), (BImc) or (BImd) gives a general structure for such materials wherein Rqa, Rqb and Rqc are independently a C-4 to C-8 alkyl group, Rqe is a valence bond, an arylene moiety, a C-1 to C-4 alkylene moiety, an alkenyl moiety (—C(Rqf)═C(Rqg)—, wherein Rqf and Rqg are independently H or a C-1 to C-4 alkyl). Structure (BIme) gives a specific example of such a material.

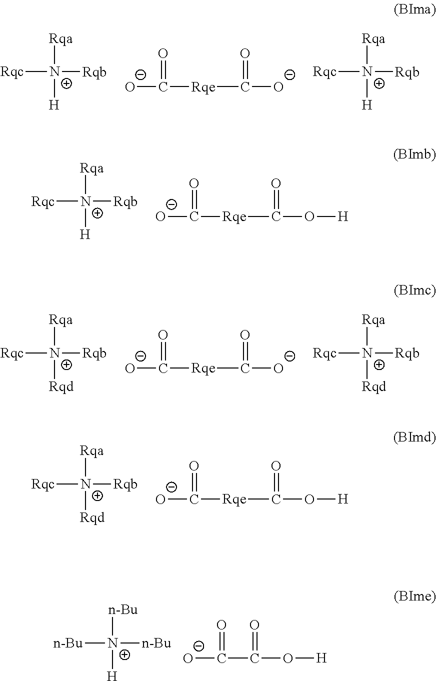

This base additive component, if present, ranges from about 0.0001 wt. % to about 0.020 wt. % of total solids.

### Acrylic Resins with Acid Cleavable Groups for Positive Chemically Amplified Photoresists

For the Positive chemically amplified photoresist that contain an acrylate resin, as describe herein, suitable resins are ones that contain an acid cleavable group which, when cleaved by photo-acid, renders the resin soluble in an aqueous base developer, as non-limiting examples, those as described in U.S. Pat. Nos. 8,017,296, 9,012,126, 8,841,062 WO2021/094350, WO2020/048957.

### Hydroxy Styrene Resins with Acid Cleavable Groups for Positive Chemically Amplified Photoresists

For the Positive chemically amplified photoresist, as described herein, which comprise a hydroxy styrene resin suitable resins of this type are ones that have an acid cleavable group, which when cleaved by photo-acid, renders the resin soluble in an aqueous base developer, for instance as non-limiting examples, those described in WO2019/224248, US2020-0183278.

### Acrylic Resins for Positive Non-Chemically Amplified Photoresists

For Positive non-chemically amplified photoresist, as described herein, suitable resins are acrylate resins which are soluble in an aqueous base developer such as those as described in WO2021/094423 as a non-limiting example.

### Phenolic Resins Soluble in Aqueous Base for Use in Positive Chemically Non-Chemically Amplified Photoresists

For Positive non-chemically amplified photoresist, as described herein, which comprise a phenolic resin such as Novolaks or resins derived from hydroxystyrene, suitable Novolak resins are herein and also, as non-limiting examples, those described in U.S. Pat. No. 6,852,465 and WO2021/094423

### Acrylic Resins for Negative-Chemically Amplified Photoresists

For the Negative chemically amplified photoresist that contains an acrylate resin, as described herein, suitable resins are acrylic resins which are soluble in an aqueous base developer such as those as described in U.S. Pat. No. 6,576,394, as a non-limiting examples.

### Acrylic Resins for Negative Non-Chemically Amplified Photoresists

For the Negative non-chemically amplified photoresist that contains an acrylate resin, as described herein, suitable resins are acrylate resins which are soluble in an aqueous base developer such those as described in U.S. Pat. No. 8,906,594 or US2020-0393758 as non-limiting examples.

### Hydroxy Styrene Resins for Negative Non-Chemically Amplified Photoresists

For the Negative non-chemically amplified photoresist that contain an hydroxystyrene resin, as described herein, suitable resins are, as non-limiting examples, is a hydroxystyrene resin which may contain optional acrylate repeat units, which are soluble in an aqueous base developer such as those as described in U.S. Pat. No. 7,601,482 as a non-limiting example.

### Organic Spin Casting Solvent

In the non-chemically amplified and chemically amplified photoresist formulations, described herein, the organic spin casting solvent component comprises one or more of butyl acetate, amyl acetate, cyclohexyl acetate, 3-methoxybutyl acetate, methyl ethyl ketone, methyl amyl ketone, cyclohexanone, cyclopentanone, ethyl-3-ethoxy propanoate, methyl-3-ethoxy propanoate, methyl-3-methoxy propanoate, methyl acetoacetate, ethyl acetoacetate, diacetone alcohol, methyl pivalate, ethyl pivalate, propylene glycol monomethyl ether (PGME), propylene glycol monoethyl ether, propylene glycol monomethyl ether propanoate, propylene glycol monoethyl ether propanoate, ethylene glycol monomethyl ether, ethylene glycol monoethyl ether, diethylene glycol monomethyl ether, diethylene glycol monoethyl ether, 3-methyl-3-methoxybutanol, N-methylpyrrolidone, dimethyl sulfoxide, gamma-butyrolactone, propylene glycol methyl ether acetate (PGMEA), propylene glycol ethyl ether acetate, propylene glycol propyl ether acetate, methyl lactate, ethyl lactate, propyl lactate, tetramethylene sulfone, propylene glycol dimethyl ether, dipropylene glycol dimethyl ether, ethylene glycol dimethyl ether or diethylene glycol dimethyl ether and gamma butyrolactone. In one aspect of this embodiment said organic spin casting solvent in only one solvent. In another aspect of this embodiment said organic spin casting solvent is a mixture of two or more solvents. In another aspect it is a mixture of three solvents, in one aspect of this embodiment the solvent is a mixture of PGMEA, 3-methoxybutyl acetate and gamma-butyrolactone. In another aspect of this embodiment the solvent mixture is this mixture where PGMEA ranges from about 55 wt. % to about 80 wt. %, 3-methoxybutyl acetate ranges from about 5 wt. % to about 20 wt. %, and gamma butyrolactone ranges from about 1 wt. % to about 2 wt. %, where the sum of the wt. % of these individual components is equal to 100 wt. %.

### Optional Components

The photoresist formulation as described herein may, optionally further comprises at least one optional surface leveling agents, such as one or more surfactants. In this embodiment, there is no particular restriction with regard to the surfactant, and the examples of it include a polyoxyethylene alkyl ether such as polyoxyethylene lauryl ether, polyoxyethylene stearyl ether, polyoxyethylene cetyl ether, and polyoxyethylene olein ether; a polyoxyethylene alkylaryl ether such as polyoxyethylene octylphenol ether and polyoxyethylene nonylphenol ether; a polyoxyethylene polyoxypropylene block copolymer; a sorbitane fatty acid ester such as sorbitane monolaurate, sorbitane monovalmitate, and sorbitane monostearate; a nonionic surfactant of a polyoxyethylene sorbitane fatty acid ester such as polyoxyethylene sorbitane monolaurate, polyoxyethylene sorbitane monopalmitate, polyoxyethylene sorbitane monostearate, polyethylene sorbitane trioleate, and polyoxyethylene sorbitane tristearate; a fluorinated surfactant such as F-Top EF301, EF303, and EF352 (manufactured by Jemco Inc.), Megafac F171, F172, F173, R08, R30, R90, and R94 (manufactured by Dainippon Ink & Chemicals, Inc.), Florad FC-430, FC-431, FC-4430, and FC-4432 (manufactured by Sumitomo 3M Ltd.), Asahi Guard AG710, Surflon S-381, S-382, S-386, SC101, SC102, SC103, SC104, SC105, SC106, Surfinol E1004, KH-10, KH-20, KH-30, and KH-40 (manufactured by Asahi Glass Co., Ltd.); an organosiloxane polymer such as KP-341, X-70-092, and X-70-093 (manufactured by Shin-Etsu Chemical Co., Ltd.); and an acrylic acid or a methacrylic acid polymer such as Polyflow No. 75 and No. 95 (manufactured by Kyoeisha Chemical Co. Ltd.). When a surfactant is present in one embodiment it ranges from about 0.01 wt. % to about 0.3 wt. % of total solids.

### Compositions Comprising a Thiol Derivative and an Organic Spin Casting Solvent and the Process of Using These to Produce an Anisotropically Etched Metal Substrate,

### Compositions Comprising a Thiol Derivative and an Organic Spin Casting Solvent

Another aspect of this invention is a composition which comprises
a thiol derivative where the thiol moiety is attached to an SP2 carbon which is part of a ring which has structures (H1), (H2) (H3), or (H4), and
an organic spin casting solvent wherein said thiol derivative comprises about 1 wt. % to about 10 wt. % of the composition, and said thiol derivative comprises from about 98 wt. % to 100 wt. % of total solids, and further wherein,
in said structure (H1), Xt is selected from the group consisting of N(Rt₃), C(Rt₁)(Rt₂), O, S, Se, and Te;
in said structure (H2), Y is selected from the group consisting of C(Rt₃) and N;
in said structure (H3), Z is selected from the group consisting of C(Rt₃) and N; and
in said structure (H4), where Arene is selected from an unsubstituted phenyl, a substituted phenyl, an unsubstituted polycyclic arene moiety and a substituted polycyclic arene moiety, Rt₁, Rt₂, and Rt₃ are independently selected from the group consisting of H, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms,
Rt₄ is independently selected from the group consisting of H, OH, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms,

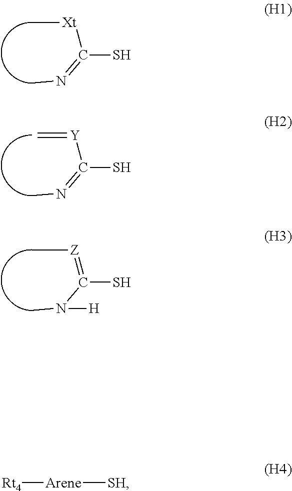

In one aspect of the composition of said thiol derivative in an organic solvent, said composition consists of only these two components.

In one aspect of the composition of said thiol derivative in an organic spin casting solvent, said thiol derivative is present at a loading from about 1.25 wt. % to about 10 wt. % of the composition. In one aspect of this embodiment, it is present at a loading from about 1.5 wt. % to about 9.75 wt. % of the composition. In one aspect of this embodiment, it is present at a loading from about 1.75 wt. % to about 9.50 wt. % of the composition. In one aspect of this embodiment, it is present at a loading from about 2 wt. % to about 9.25 wt. % of the composition. In one aspect of this embodiment, it is present at a loading from about 2.25 wt. % to about 9 wt. % of the composition. In one aspect of this embodiment, it is present at a loading from about 2.5 wt. % to about 8.75 wt. % of the composition. In one aspect of this embodiment, it is present at a loading from about 2.75 wt. % to about 8.5 wt. % of the composition. In one aspect of this embodiment, it is present at a loading from about 3 wt. % to about 8.25 wt. % of the composition. In one aspect of this embodiment, it is In one aspect of this embodiment, it is present at a loading from about 3.25 wt. % to about 8 wt. % of the composition. In one aspect of this embodiment, it is present at a loading from about 3.5 wt. % to about 7.75 wt. % of the composition. In one aspect of this embodiment, it is present at a loading from about 3.75 wt. % to about 7.5 wt. % of the composition. In one aspect of this embodiment, it is present at a loading from about 4 wt. % to about 7.25 wt. % of the composition. In one aspect of this embodiment, it is present at a loading from about 4.25 wt. % to about 7 wt. % of the composition.

In one aspect of of the composition of said thiol derivative in an organic spin casting solvent, the thiol derivative is a heterocyclic thiol derivative having either structure (H1), (H2) or (H3). In this embodiment it may be selected from any one of the heterocyclic thiol derivatives as described as suitable for use in the above-described photoresist composition. For instance, the heterocylic thiol materials having structure (H5) to (H23), or any one of the heterocyclic thiol compound enumerated by their chemical names in the section pertaining to the photoresist compositions comprising these materials.

In one aspect of the composition of said thiol derivative in an organic spin casting solvent, said thiol derivative has structure (H2).

In one aspect of the composition of said thiol derivative in an organic spin casting solvent, said thiol derivative has structure (H3).

In one aspect of the composition of said thiol derivative in an organic spin casting solvent, has structure (H1).

In one aspect of the composition of said thiol derivative in an organic spin casting solvent, said thiol derivative has structure (H1) and where Xt is N(Rt₃).

In one aspect of the composition of said thiol derivative in an organic spin casting solvent, said thiol derivative has structure (H1-A), wherein X₁ is N, X₂ and X₃ are individually selected from the group consisting of N, and C(Rt₃) and Rx₁, Rx₂, Rx₃, Rx₄, and Rx₅ are individually selected from the group consisting of H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4), and Rt₃ in C(Rt₃) is independently selected from the group consisting of H, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms.

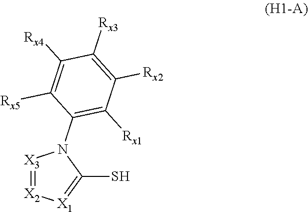

In one aspect of the composition of said thiol derivative in an organic spin casting solvent, said thiol derivative has structure (H1-B), wherein Rx, is selected from the group consisting of H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4), Rc₂ is selected from H and a C-1 to C-8 alkyl, Rc₁ is selected from H and a C-1 to C-8 alkyl.

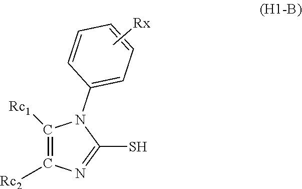

In one aspect of the composition of said thiol derivative in an organic spin casting solvent, said thiol derivative has structure (H1-C), wherein Rc₂ is selected from H and a C-1 to C-8 alkyl, and Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4).

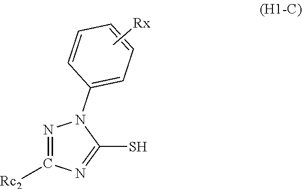

In one aspect of the composition of said thiol derivative in an organic spin casting solvent, said thiol derivative has structure (H1-D), wherein Rc1 is selected from H and a C-1 to C-8 alkyl, and Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4).

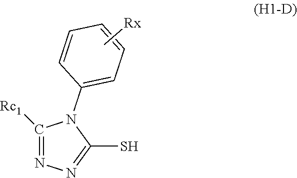

In one aspect of the composition of said thiol derivative in an organic spin casting solvent, said thiol derivative has structure (H1-E), wherein Rx is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4).

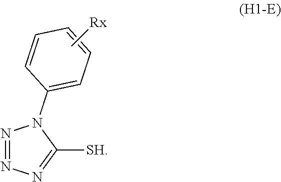

In one aspect of the composition of said thiol derivative in an organic spin casting solvent, said thiol derivative has structure (H1-EA), wherein Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4).

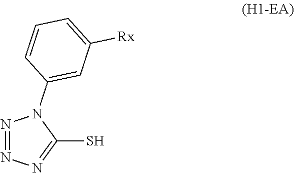

In one aspect of the composition of said thiol derivative in an organic spin casting solvent, said thiol derivative has structure (H1-EB), wherein Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4).

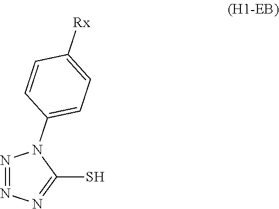

In one aspect of the composition of said thiol derivative in an organic spin casting solvent, said thiol derivative has structure (H1-EC), or structure (H1-ED).

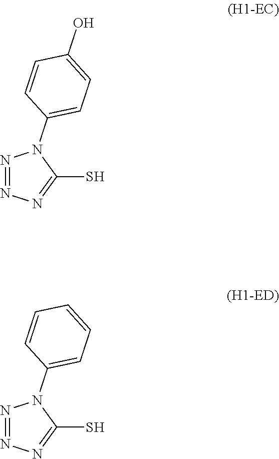 [SMILES: Oc1ccc(-n2nnnc2S)cc1 ; Sc1nnnn1-c1ccccc1]

In one aspect of the composition of said thiol derivative in an organic spin casting solvent, said thiol derivative has structure (H1-EC).

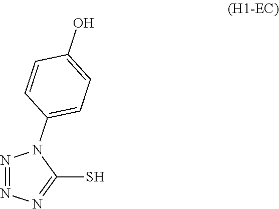 [SMILES: Oc1ccc(-n2nnnc2S)cc1]

In one aspect of the composition of said thiol derivative in an organic spin casting solvent, said thiol derivative has structure (H1-ED).

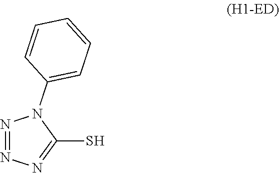 [SMILES: Sc1nnnn1-c1ccccc1]

In one aspect of the composition of said thiol derivative in an organic spin casting solvent, said thiol derivative has structure (H1-EE)),

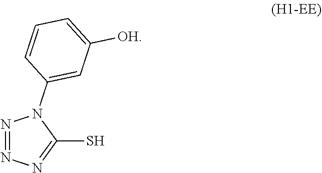 [SMILES: Oc1cccc(-n2nnnc2S)c1]

In one aspect of the composition of said thiol derivative in an organic spin casting solvent, said thiol derivative has structure (H4) where Arene moiety is selected from an unsubstituted phenyl, a substituted phenyl, an unsubstituted polycyclic arene moiety and a substituted polycyclic arene moiety.

In one aspect of the composition of said thiol derivative in an organic spin casting solvent, said arene is a substituted or unsubstituted polycyclic arene.

In one aspect of the composition of said thiol derivative in an organic spin casting solvent, said Arene is selected from naphthalene, anthracene and pyrene.

In one aspect of the composition of said thiol derivative in an organic spin casting solvent, said thiol derivative has structure (H4) and said Arene is a substituted or unsubstituted phenyl.

In one aspect of the composition of said thiol derivative in an organic spin casting solvent, said thiol derivative has structure (H4) and said Arene is an unsubstituted phenyl.

In one aspect of the composition of said thiol derivative in an organic spin casting solvent, said thiol derivative has structure (H4-A), wherein R_{H4a}, R_{H4b}, R_{H4c}, R_{H4d}, R_{H4e}, are individually selected from H, OH, a halide, a C-1 to C-8 alkyl, an unsubstituted aromatic group having 6 to 20 carbon atoms, an aromatic group having 6 to 20 carbon atoms substituted with at least one hydroxy, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4.

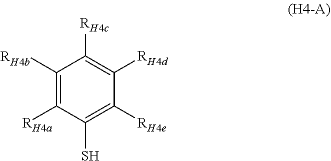

In one aspect of the composition of said thiol derivative in an organic spin casting solvent, said thiol derivative has structure (H4-B), wherein R_{H4} is selected from H, OH, a halide, a C-1 to C-8 alkyl, an unsubstituted aromatic group having 6 to 20 carbon atoms, an aromatic group having 6 to 20 carbon atoms substituted with at least one hydroxy, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4.

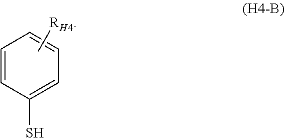

In one aspect of the composition of said thiol derivative in an organic spin casting solvent, said thiol derivative has structure (H4-C), wherein R_{4H} is selected from H, OH, a halide, a C-1 to C-8 alkyl, an unsubstituted aromatic group having 6 to 20 carbon atoms, an aromatic group having 6 to 20 carbon atoms substituted with at least one hydroxy, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4.

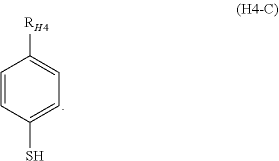

In one aspect of the composition of said thiol derivative in an organic spin casting solvent, said thiol derivative has structure (H4-D), wherein Rx₁ is selected from H, OH, a halide, a C-1 to C-8 alkyl, an unsubstituted aromatic group having 6 to 20 carbon atoms, an aromatic group having 6 to 20 carbon atoms substituted with at least one hydroxy, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4.

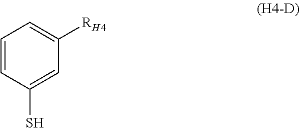

In one aspect of the composition of said thiol derivative in an organic spin casting solvent, said thiol derivative has structure (H4-E).

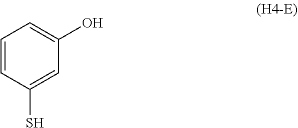

In one aspect of the composition of said thiol derivative in an organic spin casting solvent, said thiol derivative has structure (H4-F).

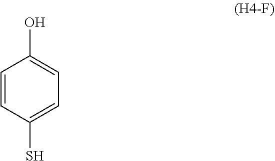

In one aspect of the composition of said thiol derivative in an organic spin casting solvent, said organic spin casting solvent component comprises one or more of butyl acetate, amyl acetate, cyclohexyl acetate, 3-methoxybutyl acetate, methyl ethyl ketone, methyl amyl ketone, cyclohexanone, cyclopentanone, ethyl-3-ethoxy propanoate, methyl-3-ethoxy propanoate, methyl-3-methoxy propanoate, methyl acetoacetate, ethyl acetoacetate, diacetone alcohol, methyl pivalate, ethyl pivalate, propylene glycol monomethyl ether (PGME), propylene glycol monoethyl ether, propylene glycol monomethyl ether propanoate, propylene glycol monoethyl ether propanoate, ethylene glycol monomethyl ether, ethylene glycol monoethyl ether, diethylene glycol monomethyl ether, diethylene glycol monoethyl ether, 3-methyl-3-methoxybutanol, N-methylpyrrolidone, dimethyl sulfoxide, gamma-butyrolactone, propylene glycol methyl ether acetate (PGMEA), propylene glycol ethyl ether acetate, propylene glycol propyl ether acetate, methyl lactate, ethyl lactate, propyl lactate, tetramethylene sulfone, propylene glycol dimethyl ether, dipropylene glycol dimethyl ether, ethylene glycol dimethyl ether or diethylene glycol dimethyl ether.

In one aspect of the composition of said thiol derivative in an organic spin casting solvent, said organic spin casting solvent is selected from propylene glycol monomethyl ether (PGME), propylene glycol methyl ether acetate (PGMEA) and mixtures thereof.

In one aspect of all the composition of said thiol derivatives in an organic spin casting solvent, used in the two-step process, where this composition is used to coat a metallic substrate prior to coating with a photoresist, patterning, and wet etching, described herein, it may contain as an optional ingredient a surfactant or levelling agent as described herein for the photoresist formulations which contain said thiol derivatives.

### A Process of Patterning a Metal Substrate, Using a Composition of Said Thiol Derivative in an Organic Spin Casting Solvent

Another aspect of this invention is a process of patterning a metal substrate to produce an anisotropically etched metal substrate which comprises the following steps:
ia) cleaning a metal substrate overlying a semiconductor with a 1 to 5 wt. % aqueous solution of a tri or dicarboxylic acid, followed by a distilled water rinse to obtain a cleaned metal substrate,
iia) spin drying the cleaned metal substrate,
iiia) applying the composition of said thiol derivatives in an organic spin casting solvent as described herein on the cleaned and dry metal substrate to obtain a treated metal substrate,
iva) baking the treated metal substrate to remove solvent at a temperature between 90 and 120° C., then rinsing with an organic spin casting solvent.
va) applying a photoresist developable after UV irradiation whit aqueous base to the treated and dry metal substrate to form a photoresist coating,
via) baking the photoresist coating to remove solvent at a temperature between 90 and 120° C.,
viia) patterning the photoresist with UV radiation followed by development with an aqueous base developer, to obtain a patterned of photoresist etch barrier overlying the metal substrate,
viiia) using the patterned photoresist as a etch barrier, treat with a wet acidic chemical etchant to produce an anisotropically etched metal pattern, overlaid with the patterned photoresist etch barrier,
viva) remove the overlying patterned photoresist etch barrier with a stripper, producing an anisotropically etched metal substrate.

In one aspect of this process the metal substrate is a metal substrate overlying a semiconductor substrate and further wherein step viva) produces an anisotropically etched metal substrate overlying a semiconductor substrate.

In another aspect of this process said metal substrate, is selected from a Copper substrate, an Aluminum substrate, an aluminum alloy substrate, silver, gold, nickel, and tungsten

In another aspect of this embodiment the metal substrate is a copper substrate. In another aspect of this embodiment the metal substrate is aluminum. In another aspect of this embodiment the metal substrate is an aluminum alloy. In another aspect of this embodiment the metal substrate is a silver substrate. In another aspect of this embodiment the metal substrate is a gold substrate. In another aspect of this embodiment the metal substrate is a nickel substrate. In another aspect of this embodiment the metal substrate is a tungsten substrate.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Chemicals

Unless otherwise indicated all chemicals were obtained from Millipore Sigma. Commercial photoresist and rinse solutions unless otherwise indicated were obtained from EMD Performance Materials Corp.

### Coating of Formulations

All formulations were tested on 6 or 8″ diameter Si and Cu wafers. The Si wafers were rehydration baked and vapor primed with hexamethyldisilazane (HMDS). The Cu wafers were silicon wafers coated with 5,000 Angstroms of silicon dioxide, 250 Angstroms of tantalum nitride, and 3,500 Angstroms of Cu (PVD deposited).

### Imaging

The wafers were exposed on SUSS MA200 CC Mask Aligner or on ASML 250 i-line stepper. The resist was waited for 10-60 mins without post exposure baking and then puddle developed for 120 to 360 seconds in AZ® 300 MIF (0.26N aqueous solution of tetramethyl ammonium hydroxide=TMAH) at 23° C. The developed resist images were inspected using Hitachi S4700 or AMRAY 4200L electron microscopes.

### Coating with Formulations

All formulations were tested on 8″ diameter Si and Cu wafers.

### Contact Angle Measurements

The contact angle of surfaces was determined with Dataphysics Contact Angle System OCA.

### Imaging of Coated Wafers

The coated wafers were exposed on SUSS MA200 CC Mask Aligner or on ORC i-line stepper. The wafer was baked at 100° C. for 100 second and then puddle developed for 120-360 seconds in AZ® 300 MIF (0.26N aqueous solution of tetramethyl ammonium hydroxide=TMAH) at 23° C. The developed resist images on metal substrates were inspected using Hitachi S4700 or AMRAY 4200L electron microscopes.

### Metal Etching

Metal substrate etched with either the following one step or two step procedures examples were etched with specific wet etchants defined by the particular metal or metal stacks to remove metal in areas not covered by patterned photoresist. Table 1 gives a summary of the etching conditions used for different metals.

In the two-step procedure the inventive thiol derivatives with the sulfur attached to an SP2 carbon in a spin casting solvent solution were used to prime a metal substrate, prior to coating with photoresist, then photoresist was coated on this primed substrate imaged, developed it and the metal substrate not covered by patterned photoresist was wet etched.

In the two step process the inventive thiol derivatives were added to commercial photoresists, and this modified commercial photoresist, was coated on a metal substrate imaged, developed it and the metal not covered by patterned photoresist was wet etched.

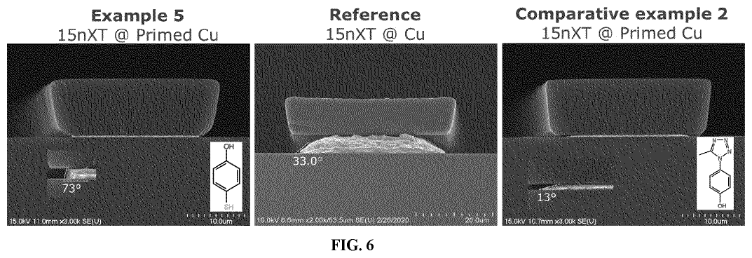

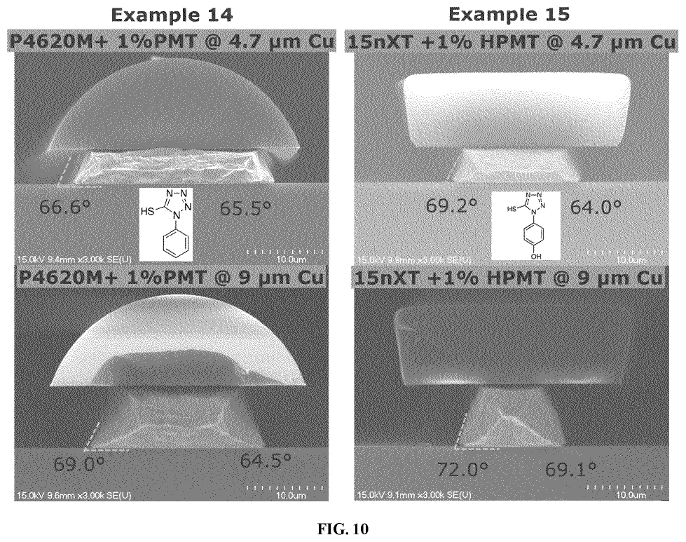

TABLE 1
Wet Etching Condition Employed for Different Metals
Used in Both One Step and Two Step Process

| | | Etching |
|---|---|---|
| Metal | Etchant | condition |
| Ag (4-5 micron) | H₃PO₄/HNO₃/ | 850 s, 35° C. |
| | CH₃COOH/H₂O | |
| Cu (0.35-9 micron) | H₃PO₄/H₂O₂/H₂O | 600-900 s, 25° C. |
| Most wet etch example were done | | |
| with 4.7-micron Cu | | |
| FIG. 6 showed example with 0.35 | | |
| micron (350 nm) | | |
| FIG. 10 showed examples with 9 | | |
| micron | | |
| Al (4-5 micron) | H₃PO₄/H₂O₂/H₂O | 100 s, 25° C. |
| Cold be a typical Al alloy | | |
| contains 0-2% Si and/or 0-4% | | |
| Cu | | |

### Two-Step Process Procedure

### Metal Substrate Priming

PMT (5-Mercapto-1-phenyl-1H-tetrazole) or its analog, e.g. 1-(4-Hydroxyphenyl)-5-mercapto-1H-tetrazole), 5-Mercapto-1-(4-methoxyphenyl)-1H-tetrazole, 1-(4-Ethoxyphenyl)-5-mercapto-1H-tetrazole, etc. was dissolved in an organic solvent (e.g. PGMEA) to form a 1-5 wt. % solution. The resulting solution was used to spin-coated on a metal substrate (AlSiCu, Cu, Ag, etc.). After applying a soft bake at 90-120° C., the excess amount of PMT-type materials was rinsed off by using AZ® EBR 70/30, forming a PMT-primed metal substrate with distinct a water contact angle compared with the unprimed metal substrate. The general procedure was as follows:

The metal substrate was cleaned by a 2% citric acid aq. solution (puddle for 2 min followed by DI water rinse and spin-dry);

The primer solution was spin-coated on the cleaned metal substrate (1500 rpm 30 s)

The coated substrate was baked (110 C for 1-2 min) to allow chemical grafting of the primer to the metal substrate

The excess amount primer was then rinsed with AZ® EBR 70/30 puddles and sprays, followed by spin-dry to get the primed metal substrate.

### Photoresist Patterning

A photoresist (e.g. Novolak-DNQ types, chemically amplified types or photopolymer types) was applied and patterned on the PMT-primed metal substrate using standard photolithography techniques to obtain the metal substrate patterned with the chosen photoresist as follows:

The primed metal substrate was coated with the chosen photoresist (specific coating parameters are determined by the chosen resist and the target resist film thickness);

The resulting substrate coated with the chosen resist was exposed in an typical exposure tool (SUSS broad band aligner or ASLM i-line stepper), the specific exposure parameters are determined by the target resist film thickness;

The espoused substrate was developed with resist developer (e.g. AZ MIF 300) to yield the pattered metal substrate.

### Metal Etch

### Metal Etch with Two Step Process

The resulting metal substrate patterned primed with the inventive thiol derivative solutions-containing photoresist was treated with specific wet etchants defined by the particular metal or metal stacks to remove unwanted metal without photoresist protection to yield certain metal structure defined by the mask pattern. Often a hard bake prior to the wet etch is needed to allow steepest metal side wall profile, and the optimal hard bake temperature varies for the specific photoresist. Table 1 gives general etching conditions for different metals.

The general process is as follows:

The resist-pattered metal substrate was first baked at 90-120° C., depending on the chosen resist;

The resist-pattered metal substrate was then immersed sequentially in the etchant bathes and etched under the specific condition chosen for the specific metal stacks.

In between each etchant, a DIW rinse was applied. And at the end of the through-stack etch, the substrate was rinsed with 50° C. DIW and dried under N₂.

The post etch substrate could be treated with a remover (e.g. AZ® 910) to stripe the resist for better analysis of the etch results.

### Example 1

An electrodeposited copper wafer was primed using the following process:
Cleaned by a 2% citric acid aq. solution then spun-dried.
Spin-coated by 2 mL 5 wt. % 1-(phenyl)-5-mercapto-1H-tetrazole) solution in PGMEA;
Baked at 110° C. for 1 min;
Rinsed with AZ® EBR 70/30;

The water contact angle of the primed Cu wafer is ˜58°, compared to the pristine Cu wafer's ˜66°

The primed wafer was then patterned by AZ® P4620M, a Novolak-DNQ positive-tone photoresist. After etching the copper in a H₃PO₄/H₂O₂-based etchant, a steep metal side wall a taper angle ˜65° was obtained, in contrast to that of a reference sample of pristine copper wafer patterned by AZ® P4620M ˜35°.

### Example 2

An electrodeposited copper wafer was primed using the following process:
Cleaned by a 2 wt. % citric acid aq. solution then spin-dried;
Spin-coated by 2 mL 5 wt. % 1-(phenyl)-5-mercapto-1H-tetrazole) solution in PGMEA;
Baked at 110° C. for 1 min;
Rinsed with AZ® EBR 70/30;

The water contact angle of the primed Cu wafer is ˜16°, compared to the pristine Cu wafer's ˜66°

The primed wafer was then patterned by AZ® P4620M, a Novolak-DNQ positive-tone photoresist. After etching the copper in a H₃PO₄/H₂O₂-based etchant, a steep metal side wall a taper angle ˜65° was obtained, in contrast to that of a reference sample of pristine copper wafer patterned by AZ® P4620M ˜35°.

### Comparative Example 1

An electrodeposited copper wafer was primed using the following process:
Cleaned by a 2 wt. % citric acid aq. solution then spin-dried.
Spin-coated by 2 mL 5 wt. % 3-(2′-ethyl-4′-(4-pentylcyclohexyl)-[1,1′-biphenyl]-4-yl)propane-1-thiol in PGMEA;
Baked at 110° C. for 1 min;
Rinsed with AZ® EBR 70/30;

The water contact angle of the primed Cu wafer is ˜65°, compared to the pristine Cu wafer's ˜66°

The primed wafer was then patterned by AZ® P4620M, a Novolak-DNQ positive-tone photoresist. After etching the copper in a H₃PO₄/H₂O₂-based etchant, a steep metal side wall a taper angle ˜35° was obtained, in contrast to that of a reference sample of pristine copper wafer patterned by AZ® P4620M ˜35°. In addition, due to the much larger undercut, the resist peeled off from the metal structure during the etch process.

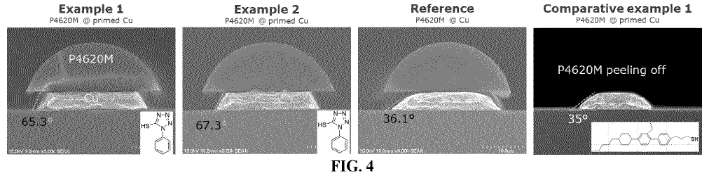

FIG. 4 shows a cross sectional SEM pictures which compares the patterned photoresist during which resulted from Example 1 and 2 where the Cu wafer was primed with the thiol derivative 1-(phenyl)-5-mercapto-1H-tetrazole) in solution in PGMEA showing anisotropic wet etching of the Cu, as shown by the large angles with the substrate of the etched Cu. FIG. 4 also shows the wet etching results obtained with a Reference Cu wafer which was not treated with this solution where a much shallower angle was obtained indicative of isotropic etching resulting from poor adhesion of the overlying patterned photoresist to the Cu underneath. FIG. 4 also shows was occurred during wet etching Comparative Example 1 where an aliphatic thiol derivative, (where the thiol is not attached to an SP2 carbons), in solution in PGMEA was used to treat the Cu wafer; in this instance as for the untreated Cu wafer a very shallow angle was observed for the etch Cu indicative of isotropic etch, surprisingly treating with this aliphatic thiol gave even worse results as the overlying patterned photoresist lost adhesion during the chemical wet etch.

### Example 3

An electrodeposited copper wafer was primed using the following process:
It was cleaned with a 2 wt. % citric acid aq. solution then spun-dried,
Spin-coated with 2 mL 5 wt. % 5-Mercapto-1-phenyl-1H-tetrazole solution in PGMEA;
baked at 110° C. for 1 min.
rinsed with AZ® EBR 70/30.

The water contact angle of the primed Cu wafer was ˜58°, compared to the pristine Cu wafer's ˜66°

The primed wafer was then patterned by AZ® 15nXT, a chemically amplified negative-tone photoresist. After etching the copper in a H₃PO₄/H₂O₂-based etchant, a steep metal side wall a taper angle ˜65° was obtained, in contrast to that of a reference sample of pristine copper wafer patterned by AZ® 15nXT ˜33°.

### Example 4

An electrodeposited copper wafer was primed using the following process:
Cleaned by a 2 wt. % citric acid aq. solution then spin-dried;
Spin-coated by 2 mL 5 wt. % 1-(4-Hydroxyphenyl)-5-mercapto-1H-tetrazole) in PGMEA;
Baked at 110° C. for 1 min;
Rinsed with AZ® EBR 70/30;

The water contact angle of the primed Cu wafer is ˜16°, compared to the pristine Cu wafer's ˜66°

The primed wafer was then patterned by AZ® 15nXT, a chemically amplified negative-tone photoresist. After etching the copper in a H₃PO₄/H₂O₂-based etchant, a steep metal side wall a taper angle ˜60° was obtained, in contrast to that of a reference sample of pristine copper wafer patterned by AZ® 15nXT ˜33°.

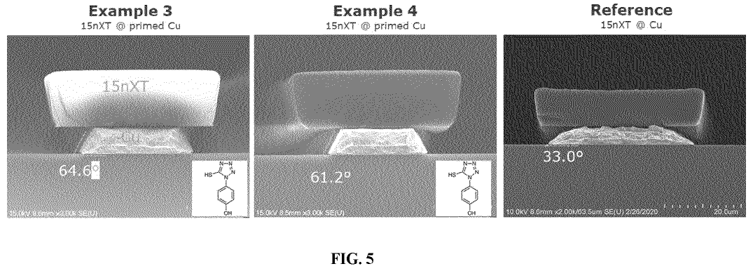

FIG. 5 shows a cross sectional SEM pictures which compares the patterned photoresist during which resulted from Example 3 and 4 where the Cu wafer was primed with the thiol derivative 1-(4-Hydroxyphenyl)-5-mercapto-1H-tetrazole) in solution in PGMEA showing anisotropic wet etching of the Cu, as shown by the large angles with the substrate of the etched Cu. FIG. 5 also shows the wet etching results obtained with a Reference Cu wafer which was not treated with this solution where a much shallower angle was obtained indicative of isotropic etching resulting from poor adhesion of the overlying patterned photoresist to the Cu underneath.

An electrodeposited copper wafer was primed using the following process:
Cleaned by a 2 wt. % citric acid aq. solution then spin-dried;
Spin-coated by 2 mL 1 wt. % 4-mercaptophenol in PGMEA;
Baked at 110° C. for 1 min;
Rinsed with AZ® EBR 70/30;

The water contact angle of the primed Cu wafer is ˜25°, compared to the pristine Cu wafer's ˜66°

The primed wafer was then patterned by AZ® 15nXT, a chemically amplified negative-tone photoresist. After etching the copper in a H₃PO₄/H₂O₂-based etchant, a steep metal side wall a taper angle ˜73° was obtained, in contrast to that of a reference sample of pristine copper wafer patterned by AZ® 15nXT ˜33°.

### Comparative Example 2

An electrodeposited copper wafer was primed using the following process:
Cleaned by a 2 wt. % citric acid aq. solution then spin-dried;
Spin-coated by 2 mL 1 wt. % 4-(5-methyl-1H-tetrazol-1-yl) phenol in PGMEA;
Baked at 110° C. for 1 min;
Rinsed with AZ® EBR 70/30;

The water contact angle of the primed Cu wafer is ˜25°, compared to the pristine Cu wafer's ˜66°

The primed wafer was then patterned by AZ® 15nXT, a chemically amplified negative-tone photoresist. After etching the copper in a H₃PO₄/H₂O₂-based etchant, a steep metal side wall a taper angle ˜13° was obtained, in contrast to that of a reference sample of pristine copper wafer patterned by AZ® 15nXT ˜33°.

FIG. 6 shows a cross sectional SEM pictures which compares the patterned photoresist during which resulted from Example 5 where the priming solution contained 4-mercaptophenol in solution in PGMEA showing anisotropic wet etching of the Cu, as shown by the large angles with the substrate of the etched Cu. FIG. 5 also shows the wet etching results obtained with a Reference Cu wafer which was not treated with this solution where a much shallower angle was obtained indicative of isotropic etching resulting from poor adhesion of the overlying patterned photoresist to the Cu. Finally, comparative example 2 where the priming solution was 4-(5-methyl-1H-tetrazol-1-yl) phenol in PGMEA (a material which does not contain thiol attached to an SP2 carbon) where a much shallower angle was obtained indicative of isotropic etching resulting from poor adhesion of the overlying patterned photoresist to the Cu underneath. All three of these experiments shown in FIG. 6 were done on 350 nm of Cu.

### ONE-STEP PROCESS

### Photoresist Formulation

The photoresist formulations were prepared as follows:
PMT (5-Mercapto-1-phenyl-1H-tetrazole) or its analog, e.g., 1-(4-Hydroxyphenyl)-5-mercapto-1H-tetrazole), 5-Mercapto-1-(4-methoxyphenyl)-1H-tetrazole, 1-(4-Ethoxyphenyl)-5-mercapto-1H-tetrazole, etc., was used as one of the components in a photoresist formulation to provide in-situ priming on a metal substrate (AlSiCu, Cu, Ag, etc.). The primary photoresist resin can be Novolak-DNQ types, chemically amplified types. The loading of PMT-type additive was from 0.3-3 wt. % of the total solids used in the photoresist formulation.

### Photoresist Patterning

The photoresist (e.g. Novolak-DNQ types, chemically amplified types or photopolymer types) containing the PMT-like additive was applied and patterned on the metal substrate using standard photolithography process.

The primed metal substrate was coated with the chosen photoresist (specific coating parameters are determined by the chosen resist and the target resist film thickness);

The resulting substrate coated with the chosen resist was exposed in a typical exposure tool (SUSS broad band aligner or ASLM i-line stepper), the specific exposure parameters are determined by the target resist film thickness.

The espoused substrate was developed with a typical resist developer (e.g. AZ MIF 300) to yield the pattered metal substrate.

### Metal Etch with One Step Process

The resulting metal substrate patterned with the PMT-containing photoresist was treated with specific wet etchants defined by the metal or metal stacks to remove unwanted metal without photoresist protection to yield certain metal structure defined by the mask pattern. Often a hard bake prior to the wet etch is needed to allow steepest metal side wall profile, and the optimal hard bake temperature varies for the specific photoresist. Table 1 gives general etching conditions for different metals.

The resist-pattered metal substrate was first baked at 90-120° C., depending on the chosen resist;

The resist-pattered metal substrate was then immersed sequentially in the etchant bathes and etched under the specific condition chosen for the specific metal stacks; In between each etchant, a DIW rinse was applied. And at the end of the through-stack etch, the substrate was rinsed with 50° C. DIW and dried under N₂.

The post etch substrate could be treated with a typical remover (e.g. AZ 910) to stripe the resist for better analysis of the etch results.

### Example 6

An electrodeposited copper wafer was first cleaned by a 2 wt. % citric acid aq. solution, then patterned by a Novolak-DNQ positive-tone photoresist, AZ® P4620M with 0.5 wt. % 5-Mercapto-1-phenyl-1H-tetrazole loading. After etching the copper in a H₃PO₄/H₂O₂-based etchant, a steep metal side wall a taper angle ˜50° was obtained, in contrast to that of a reference sample of the copper wafer patterned by AZ® P4620M ˜35°.

### Example 7

An electrodeposited copper wafer was first cleaned by a 2 wt. % citric acid aq. solution, then patterned by a Novolak-DNQ positive-tone photoresist, AZ® P4620M with 1 wt. % 5-Mercapto-1-phenyl-1H-tetrazole loading. After etching the copper in a H₃PO₄/H₂O₂-based etchant, a steep metal side wall a taper angle ˜65° was obtained, in contrast to that of a reference sample of the copper wafer patterned by AZ® P4620M ˜35°.

### Example 8

An electrodeposited copper wafer was first cleaned by a 2 wt. % citric acid aq. solution, then patterned by a Novolak-DNQ positive-tone photoresist, AZ® P4620M with 3 wt. % 5-Mercapto-1-phenyl-1H-tetrazole loading. After etching the copper in a H₃PO₄/H₂O₂-based etchant, a steep metal side wall a taper angle ˜75° was obtained, in contrast to that of a reference sample of the copper wafer patterned by AZ® P4620M ˜35°.

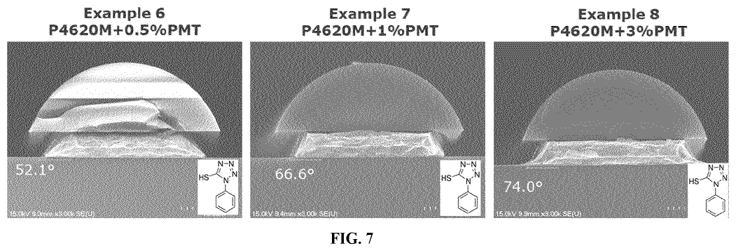

FIG. 7 shows wet etched SEM cross-section profiles obtained with Examples 6 to 7.

### Example 9

An electrodeposited copper wafer was first cleaned by a 2 wt. % citric acid aq. solution, then patterned by a chemically amplified negative-tone photoresist, AZ® 15nXT with 1 wt. % 1-(4-Hydroxyphenyl)-5-mercapto-1H-tetrazole) loading. After etching the copper in a H₃PO₄/H₂O₂-based etchant, a steep metal side wall a taper angle ˜70° was obtained, in contrast to that of a reference sample of the copper wafer patterned by AZ® 15nXT ˜33°.

### Example 10

An electrodeposited copper wafer was first cleaned by a 2 wt. % citric acid aq. solution, then patterned by a chemically amplified negative-tone photoresist, AZ® 15nXT with 3 wt. % 1-(4-Hydroxyphenyl)-5-mercapto-1H-tetrazole) loading. After etching the copper in a H₃PO₄/H₂O₂-based etchant, a steep metal side wall a taper angle ˜75° was obtained, in contrast to that of a reference sample of the copper wafer patterned by AZ® 15nXT ˜33°.

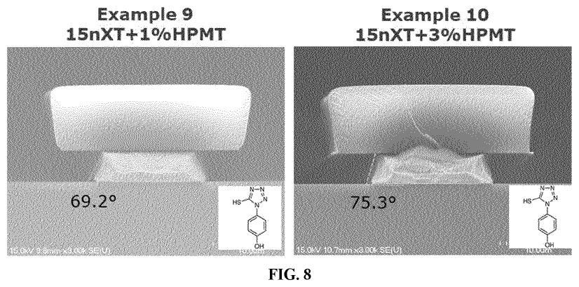

FIG. 8 shows wet etched SEM cross-section profiles obtained with Examples 9 and 10.

### Example 11

An electrodeposited copper wafer was first cleaned by a 2 wt. % citric acid aq. solution, then patterned by a Novolak-DNQ positive-tone photoresist, AZ® TD2010 with 0.1 wt. % 5-Mercapto-1-phenyl-1H-tetrazole loading. After etching the copper in a H₃PO₄/H₂O₂-based etchant, a steep metal side wall a taper angle ˜48° was obtained, in contrast to that of a reference sample of the copper wafer patterned by AZ® TD2010 ˜30°.

### Example 12

An electrodeposited copper wafer was first cleaned by a 2 wt. % citric acid aq. solution, then patterned by a Novolak-DNQ positive-tone photoresist, AZ® TD2010 with 0.75 wr. % 5-Mercapto-1-phenyl-1H-tetrazole loading. After etching the copper in a H₃PO₄/H₂O₂-based etchant, a steep metal side wall a taper angle ˜55° was obtained, in contrast to that of a reference sample of the copper wafer patterned by AZ® TD2010 ˜30°.

### Example 13

An electrodeposited copper wafer was first cleaned by a 2 wt. % citric acid aq. solution, then patterned by a Novolak-DNQ positive-tone photoresist, AZ® TD2010 with 1 wt. % 5-Mercapto-1-phenyl-1H-tetrazole loading. After etching the copper in a H₃PO₄/H₂O₂-based etchant, a steep metal side wall a taper angle ˜80° was obtained, in contrast to that of a reference sample of the copper wafer patterned by AZ® TD2010 ˜30°.

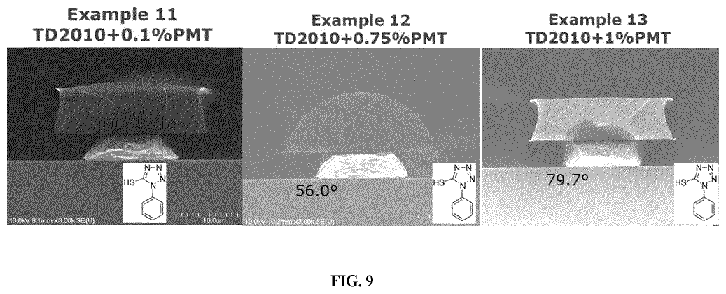

FIG. 9 shows wet etched SEM cross-section profiles obtained with Examples 11 and 12 and 13.

### Example 14

Examples 6 was repeating but in this instance using 9-micron thick Cu instead of 4.7 micron thick Cu. FIG. 10 shows a comparison of the etch results using 4.7 micron (top) and 9.0 micron (bottom); the resultant etched images which event with this much thicker Cu substrate showed good anisotropic etching of the Cu underlying the protective pattered P4520M photoresist as evidenced that a steep metal side wall a taper angle ˜70° was obtained for the etched Cu.

### Example 15

Examples 9 was repeated but in this instance using 9-micron thick Cu instead of 4.7-micron thick Cu. FIG. 10 a comparison of the etch results using 4.7 micron (top) and 9.0 micron (bottom); the resultant etched images which event with this much thicker Cu substrate showed good anisotropic etching of the Cu underlying the protective pattered P4520M photoresist as evidenced that a steep metal side wall a taper angle ˜70° was obtained for the etched Cu.

1. A photoresist composition comprising
a thiol derivative where the thiol moiety is attached to an SP2 carbon which is part of a ring which has structures (H1), (H2) (H3), or (H4), and where this thiol derivative is present in a range of about 0.5 wt. % to about 3 wt. % of total solids, wherein
in said structure (H1), Xt is selected from the group consisting of N(Rt₃), C(Rt₁)(Rt₂), O, S, Se, and Te;
in said structure (H2), Y is selected from the group consisting of C(Rt₃) and N;
in said structure (H3), Z is selected from the group consisting of C(Rt₃) and N; and
in said structure (H4), where Arene is selected from an unsubstituted phenyl, a substituted phenyl, an unsubstituted polycyclic arene moiety and a substituted polycyclic arene moiety, Rt₁, Rt₂, and Rt₃ are independently selected from the group consisting of H, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms,
Rt₄ is independently selected from the group consisting of H, OH, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms,

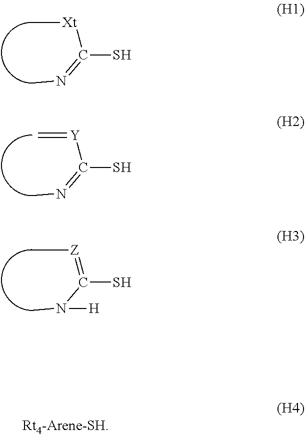

2. The composition of claim 1, wherein said thiol derivative is present at a loading from about 0.6 wt. % to about 3 wt. % of total solids.

3-15. (canceled)

15. The composition of claim 1, wherein said thiol derivative has structure (H2).

16. The composition of claim 1, wherein said thiol derivative has structure (H3).

17. The composition of claim 1, wherein said thiol derivative has structure (H1).

18. The composition of claim 1 wherein said thiol derivative has structure (H1) and where Xt is N(Rt₃).

19. The composition of claim 1, wherein said thiol derivative has structure (H1-A), wherein X₁ is N, X₂ and X₃ are individually selected from the group consisting of N, and C(Rt₃) and Rx₁, Rx₂, Rx₃, Rx₄, and Rx₅ are individually selected from the group consisting of H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4), and Rt₃ is independently selected from the group consisting of H, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms,

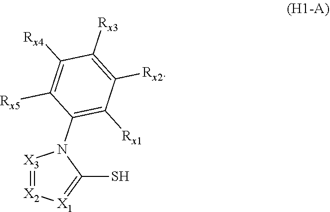

20. The composition of claim 1, wherein said thiol derivative has structure (H1-B), wherein Rx, is selected from the group consisting of H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4), Rc₂ is selected from H and a C-1 to C-8 alkyl, Rc₁ is selected from H and a C-1 to C-8 alkyl,

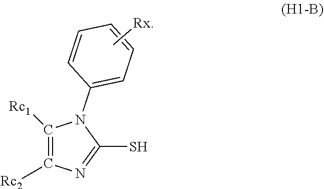

21. The composition of claim 1, wherein said thiol derivative has structure (H1-C), wherein Rc₂ is selected from H and a C-1 to C-8 alkyl, and Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4),

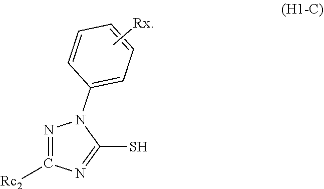

22. The composition of claim 1, wherein said thiol derivative has structure (H1-D), wherein Rc₁ is selected from H and a C-1 to C-8 alkyl, and Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4).

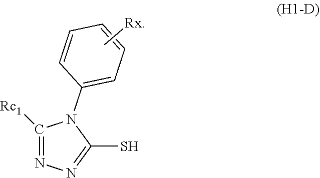

23. The composition of claim 1, wherein said thiol derivative has structure (H1-E), wherein Rx is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4),

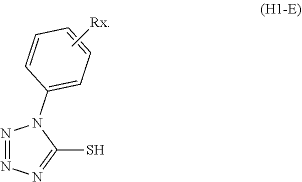

24. The composition of claim 1, wherein said thiol derivative has structure (H1-EA), wherein Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4),

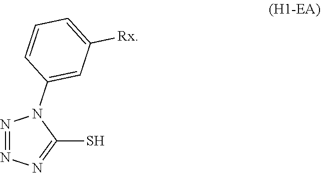

25. The composition of claim 1, wherein said thiol derivative has structure (H1-EB), wherein Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4),

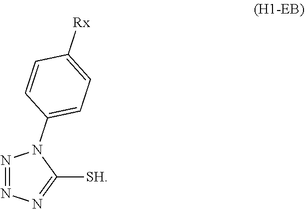

26. (canceled)

27. The composition of claim 1, wherein said thiol derivative has structure (H1-EC),

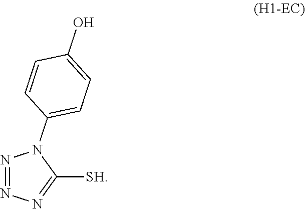 [SMILES: Oc1ccc(-n2nnnc2S)cc1]

28. The composition of claim 1, wherein said thiol derivative has structure (H1-ED),

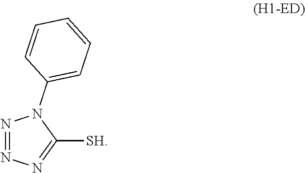 [SMILES: Sc1nnnn1-c1ccccc1]

29. The composition of claim 1, wherein said thiol derivative has structure (H1-EE),

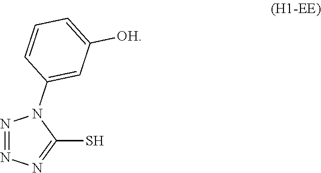 [SMILES: Oc1cccc(-n2nnnc2S)c1]

30. The composition of claim 1, wherein said thiol derivative has structure (H4), where Arene is selected from an unsubstituted phenyl, a substituted phenyl, an unsubstituted polycyclic arene moiety and a substituted polycyclic arene moiety.

31. (canceled)

32. (canceled)

33. The composition of claim 1, wherein said thiol derivative has structure (H4) and said Arene is a substituted or unsubstituted phenyl.

34-40. (canceled)

41. The composition of claim 1, wherein said photoresist composition is a positive non-chemically amplified photoresist, developable in aqueous base.

42. The composition of claim 1, wherein said photoresist composition is a positive non-chemically amplified photoresist, developable in aqueous base, comprising,
at least one Novolak type resin which is soluble in about 0.26 N TMAH,
at least one DNQ PAC component and
an organic spin casting solvent.

43. The composition of claim 1, wherein said photoresist composition is a positive non-chemically amplified photoresist, developable in aqueous base, comprising,
at least one Novolak type resin which is soluble in about 0.26 N TMAH,
at least one DNQ PAC component,
a photo-bleachable dye, and an organic spin casting solvent.

44. The composition of claim 1, wherein said photoresist composition is a positive non-chemically amplified photoresist, developable in aqueous base, comprising,
at least one Novolak type resin which is soluble in about 0.26 N TMAH,
at least one DNQ PAC component,
2000 ppm to 14,000 ppm of a surfactant, and
an organic spin casting solvent.

45. The composition of claim 1, wherein said photoresist composition is a positive non-chemically amplified photoresist, developable in aqueous base, comprising,
at least one meth(acrylate) copolymer which comprises repeat units derived from (meth)acrylic
acid, and which is solution in about 0.26 N TMAH,
at least one Novolak type resin which is soluble in about 0.26 N TMAH,
at least one DNQ PAC component, and
an organic spin casting solvent.

46. The composition of claim 1, wherein said photoresist composition is a positive chemically amplified photoresist developable in aqueous base, wherein said thiol derivative has structure (H1-E), or (H4), wherein Rx is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4), Arene is selected from an unsubstituted phenyl, a substituted phenyl, an unsubstituted polycyclic arene moiety and a substituted polycyclic arene moiety, Rt₄ is independently selected from the group consisting of H, OH, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms. unsubstituted alkynyl group having 2 to 8 carbon atoms. a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms.

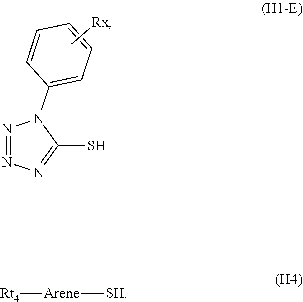

47. The composition of claim 46, wherein said photoresist composition is a positive chemically amplified photoresist developable in aqueous base, comprising,
at least one photoacid generator,
at least one polymer, comprising one or more (meth)acrylate repeat units and further comprising
one or more repeat units with at least one acid cleavable group,
an organic spin casting solvent, further wherein, and
said composition does not comprise any Novolak resin.

48. The composition of claim 46, wherein said photoresist composition is a positive chemically amplified photoresist, developable in aqueous base, comprising,
at least one photoacid generator,
at least one polymer, comprising one or more (meth)acrylate repeat units and further comprising
one or more repeat units with at least one acid cleavable group,
at least one Novolak type resin, and
an organic spin casting solvent.

49. The composition of claim 46, wherein said photoresist composition is a positive chemically amplified photoresist, developable in aqueous base, comprising,
at least one photoacid generator,
at least one DNQ PAC component,
at least one Novolak resin,
at least one polymer, comprising one or more (meth)acrylate repeat units and further comprising
one or more repeat units with at least one acid cleavable group, and
an organic spin casting solvent.

50. The composition of claim 46, wherein said photoresist composition is a positive chemically amplified photoresist, developable in aqueous base, comprising,
at least one photoacid generator,
at least one polymer, comprising one or more (meth)acrylate repeat units and further comprising
one or more repeat units with at least one acid cleavable group,
a photo bleachable dye, and
an organic spin casting solvent.

51. The composition of claim 46, wherein said photoresist composition is a positive chemically amplified photoresist comprising,
at least one polymer comprising one or more (meth)acrylate repeat units and further comprising
one or more repeat units with a at least one acid labile group,
at least one Novolak type resin which is soluble in about 0.26 N TMAH,
at least one photoacid generator (PAG), and
an organic spin casting solvent.

52. The composition of claim 46, wherein said photoresist composition is a positive chemically amplified (meth)acrylate type photoresist, developable in aqueous base, comprising,
at least one (meth)acrylate copolymer comprising a (meth)acrylic acid derived repeat unit, whose carboxylic acid is functionalized with an acid labile group, repeat units derived from at least one of styrene and benzyl (meth)acrylate, wherein said polymer becomes soluble in about 0.26 N TMAH, if the acid labile group is cleaved by photogenerated acid from the PAG, at least one PAG, and
an organic spin casting solvent.

53. The composition of claim 46, wherein said photoresist composition is a positive chemically amplified (meth)acrylate type photoresist, developable in aqueous base, comprising,
at least one (meth)acrylate copolymer comprising a (meth)acrylic acid derived repeat unit, whose carboxylic acid is functionalized with an acid labile group, repeat units derived from at least one of styrene and benzyl (meth)acrylate, wherein said polymer becomes soluble in about 0.26 N TMAH, if the acid labile group is cleaved by photogenerated acid from the PAG,
at least one Novolak type resin which is soluble in about 0.26 N TMAH,
at least one PAG, and
an organic spin casting solvent.

54. The composition of claim 46, wherein said photoresist composition is a positive chemically amplified photoresist comprising,
a component comprising a reaction product formed in the absence of an acid catalyst between (i) a Novolak polymer, (ii) a polymer comprising substituted or unsubstituted hydroxystyrene and acrylate, methacrylate or a mixture of acrylate and methacrylate, the acrylate and/or methacrylate being protected by an acid labile group that requires a high activation energy for deblocking, and (iii) a compound selected from a vinyl ether and an unsubstituted or substituted, unsaturated heteroalicyclic;
at least one PAG, and
an organic spin casting solvent.

55. The composition of claim 46, wherein said photoresist composition is a positive chemically amplified photoresist developable in aqueous base, comprising,
a component comprising a reaction product formed in the absence of an acid catalyst between (i) a Novolak polymer, (ii) a polymer comprising substituted or unsubstituted hydroxystyrene and acrylate, methacrylate or a mixture of acrylate and methacrylate, the acrylate and/or methacrylate being protected by an acid labile group that requires a high activation energy for deblocking, and (iii) a compound selected from a vinyl ether and an unsubstituted or substituted, unsaturated heteroalicyclic;
at least one polymer comprising repeat units derived from 4-hydroxystyrene, repeat units derived from an acetal protected 4-hydrostyrene, and a repeat unit derived from a (meth)acrylic acid protected with a high energy protecting group,
at least one PAG,
an organic spin casting solvent.

56. The composition of claim 1, wherein said photoresist is a negative non-chemically amplified photoresist which is developable in aqueous base wherein said thiol derivative has structure (H1-E), wherein Rx is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4),

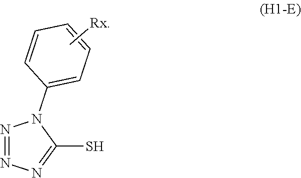

57. The composition of claim 1, wherein said photoresist is a negative non-chemically amplified photoresist which is developable in aqueous base comprising,
at least one alkali-soluble polymer, where the polymer comprises at least one unit of structure (INR), 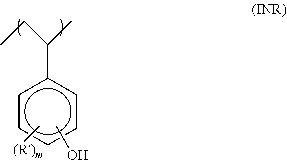
where, R′ is selected independently from hydrogen, (C₁-C₄)alkyl, chlorine and bromine, and m is an integer from 1 to 4;
at least one monomer of structure (IINR), 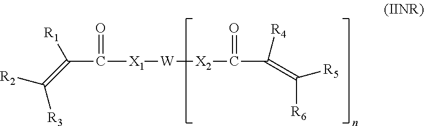
where, W is a multivalent linking group, R₁ to R₆ are independently selected from hydrogen, hydroxy, (C₁-C₂₀) alkyl and chlorine, X₁ and X₂ are independently oxygen or N-R₇, where R₇ is hydrogen or (C₁-C₂₀) alkyl, and n is an integer equal to or greater than 1; and,
at least one radical photoinitiator and
an organic spin casting solvent.

58. The composition of claim 1, wherein said photoresist composition is a negative non-chemically amplified photoresist, developable in aqueous base, comprising
at least one Novolak type resin which is soluble in about 0.26 N TMAH,
at least one radical photoinitiator,
at least one (meth)acrylate crosslinker and
an organic spin casting solvent.

59. The composition of claim 1, wherein said photoresist composition is a negative non-chemically amplified (meth)acrylate type photoresist, developable in aqueous base, comprising
at least one (meth)acrylate polymer comprising a (meth)acrylic acid derived repeat unit, a repeat unit derived from at least one of styrene and benzyl (meth)acrylate, which is soluble in about 0.26 N TMAH,
at least one radical photoinitiator,
at least one (meth)acrylate crosslinker and
an organic spin casting solvent.

60. The composition of claim 1, wherein said photoresist composition is a negative chemically amplified photoresist developable in aqueous base.

61. The composition of claim 1, wherein said photoresist composition is a negative chemically amplified photoresist developable in aqueous base, comprising,
at least one phenolic film-forming polymeric binder resin having ring bonded hydroxyl groups,
selected from a Novolak resin, a hydroxystyrene copolymer, or mixtures thereof which is soluble in 0.26 N TMAH
at least one PAG,
a crosslinking agent that forms a carbonium ion upon exposure to acid photogenerated by the PAG and which comprises an etherified aminoplast polymer or oligomer and
an organic spin casting solvent.

62. A process of patterning a metal substrate, comprising
i) cleaning a metal substrate overlying a semiconductor with a 1 to 5 wt. % aqueous solution of a tri or dicarboxylic acid, followed by distilled water rinse to obtain a cleaned metal substrate,
ii) spin drying the cleaned metal substrate,
iii) applying the composition of claim 1 on the cleaned and dry metal substrate to obtain a photoresist coating,
iv) baking the photoresist coating to remove solvent at a temperature between 90 and 120° C.,
v) patterning the photoresist with UV radiation followed by development with an aqueous base developer, to obtain a patterned of photoresist etch barrier overlying the metal substrate,
vi) using the patterned photoresist as a etch barrier, treat with a wet acidic chemical etchant to produce an anisotropically etched metal pattern, overlaid with the patterned photoresist etch barrier,
vii) remove the overlying patterned photoresist etch barrier with a stripper, producing an anisotropically etched metal substrate.

63. The process of claim 62, wherein the metal substrate is a metal substrate overlying a semiconductor substrate and step vii) produces an anisotropically etched metal substrate overlying a semiconductor substrate.

64. A composition comprising a thiol derivative where the thiol moiety is attached to an SP2 carbon which is part of a ring which either has structure (H2) or has structure (H1-E), and
an organic spin casting solvent wherein said thiol derivative is present at a loading from about 1 wt. % to about 10 wt. % of the composition, and said thiol derivative comprises from about 98 wt. % to 100 wt. % of total solids, and further wherein,
in said structure (H2), Y is selected from the group consisting of C(Rt₃) and N;
Rt₃ is selected from the group consisting of H, a substituted alkyl group having 1 to 8 carbon atoms, an unsubstituted alkyl group having 1 to 8 carbon atoms, a substituted alkenyl group having 2 to 8carbon atoms, unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms,
and where Rx is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4),

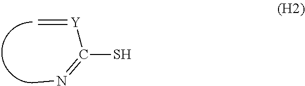

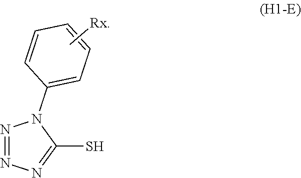

65. The composition of claim 64, wherein said thiol derivative is present at a loading from about 1.25 wt. % to about 10 wt. % of the composition.

66-105. (canceled)

106. A process of patterning a metal substrate, to produce an anisotropically etched metal substrate which comprises the following steps:
ia) cleaning a metal substrate overlying a semiconductor with a 1 to 5 wt. % aqueous solution of a tri or dicarboxylic acid, followed by a distilled water rinse to obtain a cleaned metal substrate,
iia) spin drying the cleaned metal substrate,
iiia) applying on the cleaned and dry metal substrate a composition comprising,
a thiol derivative where the thiol moiety is attached to an SP2 carbon which is part of a ring which has structures (H1), (H2) (H3), or (H4), and
an organic spin casting solvent wherein said thiol derivative is present at a loading from about 1 wt. % to about 10 wt. % of the composition, and said thiol derivative comprises from about 98 wt. % to 100 wt. % of total solids, and further wherein,
in said structure (H1), Xt is selected from the group consisting of N(Rt₃), C(Rt₁)(Rt₂), O, S, Se, and Te;
in said structure (H2), Y is selected from the group consisting of C(Rt₃) and N;
in said structure (H3), Z is selected from the group consisting of C(Rt₃) and N; and
in said structure (H4), where Arene is selected from an unsubstituted phenyl, a substituted phenyl, an unsubstituted polycyclic arene moiety and a substituted polycyclic arene moiety, Rt₁, Rt₂, and Rt₃ are independently selected from the group consisting of H, a substituted alkyl group having 1to 8 carbon atoms, an unsubstituted alkyl group having 1 to 8 carbon atoms, a substituted alkenyl group having 2 to 8 carbon atoms. unsubstituted alkenyl group having 2 to 8 carbon atoms, a substituted alkynyl group having 2 to 8 carbon atoms, unsubstituted alkynyl group having 2 to 8 carbon atoms, a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms,
Rt₄ is independently selected from the group consisting of H, OH, a substituted alkyl group having 1 to 8 carbon atoms, an unsubstituted alkyl group having 1 to 8 carbon atoms, a substituted alkenyl group having 2 to 8 carbon atoms, unsubstituted alkenyl group having 2 to 8 carbon atoms, a substituted alkynyl group having 2 to 8 carbon atoms, unsubstituted alkynyl group having 2 to 8 carbon atoms. a substituted aromatic group having 6 to 20 carbon atoms, a substituted heteroaromatic group having 3 to 20 carbon atoms, unsubstituted aromatic group having 6 to 20 carbon atoms and unsubstituted heteroaromatic group having 3 to 20 carbon atoms, 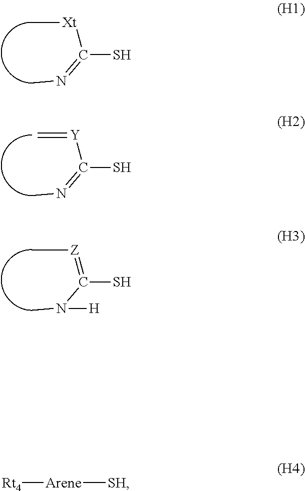
to obtain a treated metal substrate,
iva) baking the treated metal substrate to remove solvent at a temperature between 90 and 120° C., then rinsing with an organic spin casting solvent.
va) applying a photoresist developable after UV irradiation whit aqueous base to the treated and dry metal substrate to form a photoresist coating,
via) baking the photoresist coating to remove solvent at a temperature between 90 and 120° C.,
viia) patterning the photoresist with UV radiation followed by development with an aqueous base developer, to obtain a patterned of photoresist etch barrier overlying the metal substrate,
viiia) using the patterned photoresist as a etch barrier, treat with a wet acidic chemical etchant to produce an anisotropically etched metal pattern, overlaid with the patterned photoresist etch barrier,
viva) remove the overlying patterned photoresist etch barrier with a stripper, producing an anisotropically etched metal substrate.

107. The process of claim 106, wherein the metal substrate is a metal substrate overlying a semiconductor substrate and further wherein step viva) produces an anisotropically etched metal substrate overlying a semiconductor substrate.

108. (canceled)

109. The photoresist composition of claim 1 comprising a thiol derivative, wherein said thiol derivative is selected from the groups consisting of,
a thiol derivative which has structure (H1-B), wherein Rx, is selected from the group consisting of H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4), Rc₂ is selected from H and a C-1 to C-8 alkyl, Rc₁ is selected from H and a C-1 to C-8 alkyl, 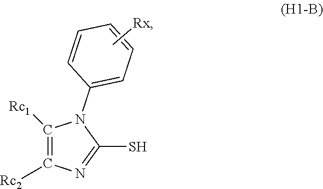
a thiol derivative which has structure (H1-C), wherein Rc₂ is selected from H and a C-1 to C-8 alkyl, and Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4), 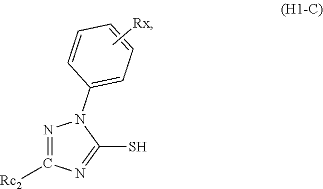
a said thiol derivative which has structure (H1-D), wherein Rc₁ is selected from H and a C-1 to C-8 alkyl, and Rx, is selected from H, OH, a halide, a C-1 to C-8 alkyl, an aryl, a C-1 to C-8 alkylenehydroxy (-alkylene-OH), a C-2 to C-8 alkyleneoxyalkyl (-alkylene-O-alkyl), and a C-5 to C-15 polyalkyleneoxyakyl (-(alkylene-O)ₚₐ-alkyl), where pa is an integer ranging from 2 to 4). 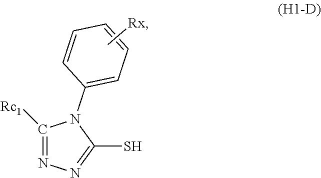
a thiol derivative has structure (H1-EC), 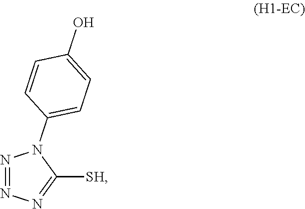 [SMILES: Oc1ccc(-n2nnnc2S)cc1]
a thiol derivative has structure (H1-EE), 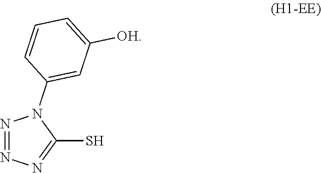 [SMILES: Oc1cccc(-n2nnnc2S)c1]
a thiol derivative of structure (H4), wherein Rt₄ is selected from an unsubstituted phenyl, a substituted phenyl, an unsubstituted polycyclic arene moiety and a substituted polycyclic arene moiety.
Rt₄-Arene-SH (H4).
